(19) United States
(12) Patent Application Publication
(10) Pub. No.: US 2025/0175145 A1
(43) Pub. Date: May 29, 2025

(54) ACOUSTIC WAVE DEVICE AND FILTER DEVICE

(71) Applicant: Murata Manufacturing Co., Ltd., Nagaokakyo-shi (JP)

(72) Inventors: Kentaro NAKAMURA, Nagaokakyo-shi (JP); Takuya YABU, Nagaokakyo-shi (JP); Ryo NAKAGAWA, Nagaokakyo-shi (JP); Katsuya DAIMON, Nagaokakyo-shi (JP)

(21) Appl. No.: 19/041,154

(22) Filed: Jan. 30, 2025

Related U.S. Application Data
(63) Continuation of application No. PCT/JP2023/026608, filed on Jul. 20, 2023.

(30) Foreign Application Priority Data
Aug. 4, 2022 (JP) 2022-125003

(51) Int. Cl. H03H 9/145; H03H 9/02; H03H 9/25; H03H 9/64

(52) U.S. Cl. CPC H03H 9/14561; H03H 9/02866; H03H 9/02889; H03H 9/02992; H03H 9/25; H03H 9/6483

(57) ABSTRACT

An acoustic wave device includes a piezoelectric layer and an IDT electrode. The IDT electrode includes first and second busbars, and first and second electrode fingers interdigitated with each other. A virtual line connecting ends of the second electrode fingers is defined as a first envelope, a virtual line connecting ends of the first electrode fingers is defined as a second envelope, and a region between the first and second envelopes is an intersection region. Shapes of the first and second electrode fingers include at least two curved portions different from each other in the intersection region. In the intersection region, a value of at least one of a duty ratio, an electrode finger pitch, and thicknesses of the first and second electrode fingers changes in one of a direction in which the value increases and the direction in which the value decreases.

### CROSS REFERENCE TO RELATED APPLICATIONS

This application claims the benefit of priority to Japanese Patent Application No. 2022-125003 filed on Aug. 4, 2022 and is a Continuation Application of PCT Application No. PCT/JP2023/026608 filed on Jul. 20, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

In the related art, acoustic wave devices are widely used for, for example, filters of mobile phones. International Publication No. 2011/108229 discloses an example of an acoustic wave device. In the acoustic wave device, an interdigital transducer (IDT) electrode is provided on a piezoelectric substrate. The shape of a plurality of electrode fingers of the IDT electrode includes a curved shape. More specifically, each electrode finger extends along a curve from the center of a region where the IDT electrodes intersect to a common electrode.

In an IDT electrode of an acoustic wave device described in International Publication No. 2011/108229, an electrode finger pitch in the central portion in the direction in which a plurality of electrode fingers extend is narrower than an electrode finger pitch at an end portion in the direction. Therefore, the effect of reducing or preventing a response of an unnecessary wave to some extent can be obtained. However, since the resonant frequency varies for each portion of the IDT electrode, there is a possibility that the resonance characteristics may deteriorate. Furthermore, unnecessary waves cannot be sufficiently reduced or prevented.

### SUMMARY OF THE INVENTION

Example embodiments of the present invention provide acoustic wave devices and filter devices each able to sufficiently reduce or prevent an unnecessary wave outside a pass band and a transverse mode and to reduce or prevent deterioration of resonance characteristics.

An acoustic wave device according to an example embodiment of the present invention includes a piezoelectric substrate including a piezoelectric layer, and an IDT electrode on the piezoelectric layer, in which the IDT electrode includes a first busbar and a second busbar facing each other, a plurality of first electrode fingers each including one end connected to the first busbar, and a plurality of second electrode fingers each including one end connected to the second busbar, the plurality of first electrode fingers and the plurality of second electrode fingers are interdigitated with each other, a virtual line connecting tip ends of the plurality of second electrode fingers is defined as a first envelope, a virtual line connecting tip ends of the plurality of first electrode fingers is defined as a second envelope, a region between the first envelope and the second envelope in the IDT electrode is an intersection region, shapes of the plurality of first electrode fingers and the plurality of second electrode fingers in a plan view include at least two curved portions in which directions where a first electrode finger and a second electrode finger are bent are different from each other in the intersection region, and in the intersection region, since a portion is closer to the first envelope or the second envelope, a value of at least one of a duty ratio, an electrode finger pitch, and thicknesses of the plurality of first electrode fingers and the plurality of second electrode fingers changes in one of a direction in which the value increases and a direction in which the value decreases.

An acoustic wave device according to another example embodiment of the present invention includes a piezoelectric substrate including a piezoelectric layer, and an IDT electrode on the piezoelectric layer, in which the IDT electrode includes a first busbar and a second busbar facing each other, a plurality of first electrode fingers each including one end connected to the first busbar, and a plurality of second electrode fingers each including one end connected to the second busbar, the plurality of first electrode fingers and the plurality of second electrode fingers are interdigitated with each other, a virtual line connecting tip ends of the plurality of second electrode fingers is defined as a first envelope, a virtual line connecting tip ends of the plurality of first electrode fingers is defined as a second envelope, a region between the first envelope and the second envelope in the IDT electrode is an intersection region, each of shapes of the plurality of first electrode fingers and the plurality of second electrode fingers in a plan view includes a shape of at least two circular or substantially circular arcs or elliptical or substantially elliptical arcs and includes at least one inflection point, the intersection region includes at least two curved regions in which each of the shapes of the plurality of first electrode fingers and the plurality of second electrode fingers in a plan view is a shape of a single circular or substantially circular arc or an elliptical or substantially elliptical arc, the intersection region includes a first edge region including the first envelope, a second edge region including the second envelope, and a central region interposed between the first edge region and the second edge region, a low acoustic velocity region with an acoustic velocity lower than an acoustic velocity in the central region is provided in at least one of the first edge region or the second edge region, and when a center of a circle including the circular or substantially circular arc of a first electrode finger and a second electrode finger or a midpoint of two focal points of an ellipse including the elliptical or substantially elliptical arc in each of the curved regions is defined as a fixed point, and a portion on any straight line passing through the fixed point in a region located in the central region of each of the curved regions is defined as an excitation portion, as the excitation portion is closer to the first envelope or the second envelope, a value of at least one of a duty ratio, an electrode finger pitch, or thicknesses of the plurality of first electrode fingers and the plurality of second electrode fingers changes in one of a direction in which the value increases and a direction in which the value decreases.

A filter device according to an example embodiment of the present invention includes a plurality of acoustic wave resonators, in which at least one of the acoustic wave resonators is an acoustic wave device according to an example embodiment of the present invention.

With acoustic wave devices and filter devices according to example embodiments of the present invention, it is possible to sufficiently reduce or prevent unnecessary waves outside a pass band and a transverse mode and to reduce or prevent deterioration of the resonance characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic plan view for describing a configuration of an IDT electrode in the first example embodiment of the present invention.

FIG. 4 is a schematic plan view of an IDT electrode in a comparative example.

FIG. 5 is a graph showing impedance frequency characteristics in the first example embodiment and the comparative example of the present invention.

FIG. 6 is a graph showing a return loss in the first example embodiment and the comparative example of the present invention.

FIG. 7 is a graph showing phase characteristics in the first example embodiment and the comparative example of the present invention.

FIG. 8 is a graph showing reverse-velocity surfaces of acoustic waves propagating in a first piezoelectric substrate and a second piezoelectric substrate.

FIG. 9 is a graph showing reverse-velocity surfaces of a longitudinal wave, a fast transversal wave, and a slow transversal wave in the first piezoelectric substrate.

FIG. 10 is a graph showing a relationship between an absolute value of an excitation angle |θ_{C1_prop}| and a duty ratio of the IDT electrode in the first example embodiment, a first modified example, and a second modified example of the present invention.

FIG. 11 is a schematic plan view of an IDT electrode in a reference example.

FIG. 12 is a graph showing a return loss in the first example embodiment and the reference example of the present invention.

FIG. 13 is a graph showing impedance frequency characteristics in the first example embodiment and the reference example of the present invention.

FIG. 14 is a graph showing phase characteristics in the first example embodiment and the reference example of the present invention.

FIG. 15 is a schematic elevational cross-sectional view of an acoustic wave device according to a third modified example of the first example embodiment of the present invention.

FIG. 16 is a schematic elevational cross-sectional view of an acoustic wave device according to a fourth modified example of the first example embodiment of the present invention.

FIG. 17 is a schematic plan view of an acoustic wave device according to a second example embodiment of the present invention.

FIG. 18 is a schematic plan view for describing a configuration of an IDT electrode in the second example embodiment of the present invention.

FIG. 19 is a graph showing a relationship between an absolute value of an excitation angle |θ_{C1_prop}| and a rate of change Δpitch of an electrode finger pitch of the IDT electrode in the second example embodiment of the present invention.

FIG. 20 is a schematic plan view showing the vicinity of a gap on a first busbar side of an IDT electrode in a third example embodiment of the present invention.

FIG. 21 is a schematic plan view showing the vicinity of a gap on a first busbar side of an IDT electrode in a first modified example of the third example embodiment of the present invention.

FIG. 22 is a schematic plan view showing the vicinity of a gap on a first busbar side of an IDT electrode in a second modified example of the third example embodiment of the present invention.

FIG. 23 is a schematic plan view of an acoustic wave device according to a fourth example embodiment of the present invention.

FIG. 24 is a schematic plan view for describing a configuration of an IDT electrode in a fifth example embodiment of the present invention.

FIG. 25 is a schematic plan view of an acoustic wave device according to a first modified example of the fifth example embodiment of the present invention.

FIG. 26 is an enlarged schematic plan view showing the vicinity of a first edge region and the vicinity of a second edge region of an IDT electrode in the first modified example of the fifth example embodiment of the present invention.

FIG. 27 is a schematic plan view of an acoustic wave device according to a second modified example of the fifth example embodiment of the present invention.

FIG. 28 is an enlarged schematic plan view showing the vicinity of a first edge region and the vicinity of a second edge region of an IDT electrode in a third modified example of the fifth example embodiment of the present invention.

FIG. 29 is a schematic plan view of an acoustic wave device according to a fourth modified example of the fifth example embodiment of the present invention.

FIG. 30 is a schematic plan view of an acoustic wave device according to a sixth example embodiment of the present invention.

FIG. 31 is a schematic plan view of an acoustic wave device according to a seventh example embodiment of the present invention.

FIG. 32 is a schematic plan view of an acoustic wave device according to an eighth example embodiment of the present invention.

FIG. 33 is a graph showing a relationship between an absolute value of an excitation angle |θ_{C1_prop}| and a thickness of an electrode finger of the IDT electrode in a ninth example embodiment of the present invention.

FIG. 34 is a schematic elevational cross-sectional view of an acoustic wave device according to a tenth example embodiment of the present invention.

FIG. 35 is a graph showing a relationship between an absolute value of an excitation angle |θ_{C1_prop}| in an excitation portion of a first curved region covered with a dielectric film and a thickness of the dielectric film in the tenth example embodiment of the present invention.

FIG. 36 is a graph showing a relationship between an absolute value of an excitation angle |θ_{C1_prop}| in an excitation portion of a first curved region covered with a dielectric film and a thickness of the dielectric film in a modified example of the tenth example embodiment of the present invention.

FIG. 37 is a circuit diagram of a filter device according to an eleventh example embodiment of the present invention.

FIG. 38 is an enlarged schematic plan view showing a portion of the IDT electrode in a fifth modified example of the first example embodiment of the present invention.

FIG. 39 is a schematic elevational cross-sectional view of an acoustic wave device according to a twelfth example embodiment of the present invention.

FIG. 40 is a schematic elevational cross-sectional view of an acoustic wave device according to a thirteenth example embodiment of the present invention.

FIG. 41 is a schematic elevational cross-sectional view of an acoustic wave device according to a first modified example of the thirteenth example embodiment of the present invention.

FIG. 42 is a schematic elevational cross-sectional view of an acoustic wave device according to a second modified example of the thirteenth example embodiment of the present invention.

FIG. 43 is a schematic elevational cross-sectional view of an acoustic wave device according to a third modified example of the thirteenth example embodiment of the present invention.

### DETAILED DESCRIPTION OF THE EXAMPLE EMBODIMENTS

Hereinafter, the present invention will be clarified by describing example embodiments of the present invention with reference to the drawings.

Each example embodiment of the present invention described in the present specification is merely an example, and configurations can be partially replaced or combined with each other between different example embodiments.

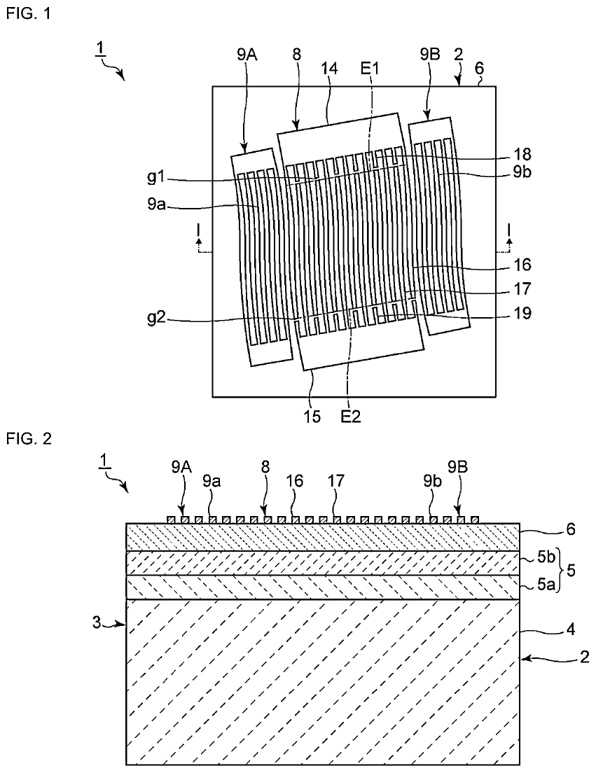

FIG. 1 is a schematic plan view of an acoustic wave device according to a first example embodiment of the present invention. FIG. 2 is a schematic cross-sectional view taken along line I-I in FIG. 1.

As shown in FIGS. 1 and 2, an acoustic wave device 1 includes a piezoelectric substrate 2. The piezoelectric substrate 2 is a substrate having piezoelectricity. Specifically, as shown in FIG. 2, the piezoelectric substrate 2 includes a support 3 and a piezoelectric layer 6. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. A layer configuration of the piezoelectric substrate 2 is not limited to the above-described example. For example, the intermediate layer 5 may be a single layer dielectric film. Alternatively, the piezoelectric substrate 2 may be a substrate including only the piezoelectric layer 6.

As shown in FIG. 1, the IDT electrode 8 is provided on the piezoelectric layer 6. The IDT electrode 8 includes a plurality of first electrode fingers 16 and a plurality of second electrode fingers 17. In the present example embodiment, the shapes of the plurality of first electrode fingers 16 and the plurality of second electrode fingers 17 in a plan view are shapes in which two circular or substantially circular arcs are connected to each other. More specifically, the shape is a shape in which the circular or substantially circular arcs of two circles including centers at positions different from each other and having the same or substantially the same radius are connected to each other. The centers of the two circles face each other with the IDT electrode 8 interposed therebetween. In the present specification, the plan view means a view from a direction corresponding to an upper side in FIG. 2. In FIG. 2, for example, the piezoelectric layer 6 side is an upper side among the piezoelectric layer 6 side of the support substrate 4 side. Hereinafter, the first electrode finger 16 and the second electrode finger 17 may be simply referred to as an electrode finger.

Each of the shapes of the plurality of first electrode fingers 16 and the plurality of second electrode fingers 17 in a plan view includes an inflection point. In the present specification, the inflection point is a point at which two different curves are connected to each other or a point at which a curve and a straight line are connected to each other. In a case where different curves are connected to each other at the inflection point, the orientations of the curved shapes are different from each other with the inflection point as a boundary. Here, the orientation of the curved shape of the electrode finger can be defined, for example, by a positional relationship between the electrode finger and a fixed point described in detail later. Specifically, the orientation of the curved shape can be defined depending on whether a fixed point determined at each portion of the curved shape in an intersection region excluding an edge region, which will be described later, is present on any side of the left or right side of the electrode finger in FIG. 1. In this case, the shape of the electrode finger includes at least two curved portions in which the bending orientation of the electrode finger is different. In the following example embodiment, two curved shapes are inverted with each other with an inflection point as a boundary.

The shapes of the plurality of first electrode fingers 16 and the plurality of second electrode fingers 17 in a plan view are not limited to the above-described shapes, and may include two or more curved portions different from each other, particularly, a shape of a circular or substantially circular arc or an elliptical or substantially elliptical arc, and may include at least one inflection point. Specifically, the curved portions different from each other may be any of circular or substantially circular arcs, elliptical or substantially elliptical arcs, or a combination of a circular or substantially circular arc and an elliptical or substantially elliptical arc. Hereinafter, details of the configuration of the IDT electrode 8 will be described.

As shown in FIG. 1, the IDT electrode 8 includes a first busbar 14, a second busbar 15, a plurality of first offset electrodes 18, and a plurality of second offset electrodes 19, in addition to the plurality of first electrode fingers 16 and the plurality of second electrode fingers 17. The first busbar 14 and the second busbar 15 face each other. One end portion of each of the plurality of first electrode fingers 16 is connected to the first busbar 14. One end portion of each of the plurality of second electrode fingers 17 is connected to the second busbar 15. The plurality of first electrode fingers 16 and the plurality of second electrode fingers 17 are interdigitated with each other.

Furthermore, one end portion of each of the plurality of first offset electrodes 18 is connected to the first busbar 14. The first electrode finger 16 and the first offset electrode 18 are alternately arranged. Each one end portion of the plurality of second offset electrodes 19 is connected to the second busbar 15. The second electrode finger 17 and the second offset electrode 19 are alternately arranged.

Each of the plurality of first electrode fingers 16, the plurality of second electrode fingers 17, the plurality of first offset electrodes 18, and the plurality of second offset electrodes 19 includes a base end portion and a tip end portion. The base end portions of the first electrode finger 16 and the first offset electrode 18 are portions connected to the first busbar 14. The base end portions of the second electrode finger 17 and the second offset electrode 19 are portions connected to the second busbar 15. The tip end portion of the first electrode finger 16 and the tip end portion of the second offset electrode 19 face each other with a gap g2 interposed therebetween. On the other hand, the tip end portion of the second electrode finger 17 and the tip end portion of the first offset electrode 18 face each other with a gap g1 interposed therebetween.

Hereinafter, the first offset electrode 18 and the second offset electrode 19 may be simply described as an offset electrode. The first busbar 14 and the second busbar 15 may be simply described as a busbar. The pitch or duty ratio of the offset electrode may be different from, for example, the electrode finger pitch or duty ratio of the IDT electrode 8 in the intersection region described later.

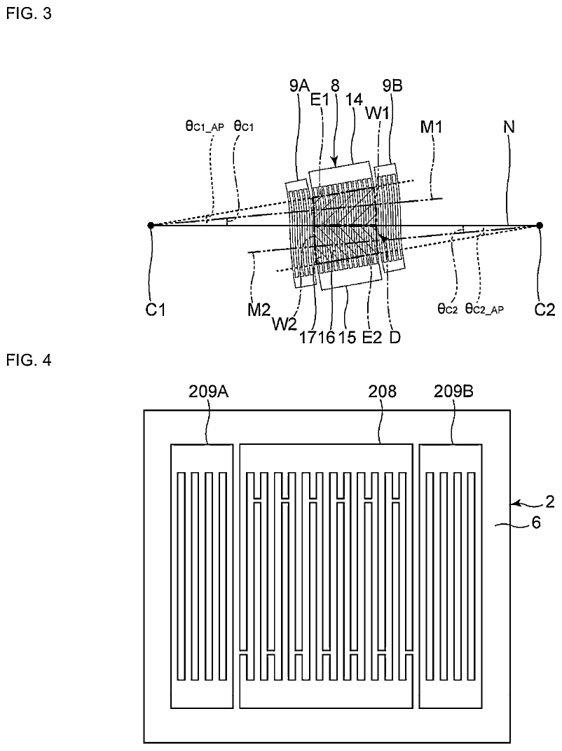

FIG. 3 is a schematic plan view for describing a configuration of the IDT electrode in the first example embodiment. In FIG. 3, each curved region described later is shown with hatching.

A virtual line connecting the tip ends of the plurality of second electrode fingers 17 is defined as a first envelope E1, and a virtual line connecting the tip ends of the plurality of first electrode fingers 16 is defined as a second envelope E2. A region between the first envelope E1 and the second envelope E2 is an intersection region D. More specifically, a region surrounded by one end electrode finger, the other end electrode finger of the plurality of electrode fingers in a direction in which the plurality of electrode fingers are arranged, the first envelope E1, and the second envelope E2 is the intersection region D. Therefore, the first envelope E1 corresponds to an end edge portion of the intersection region D on the first busbar 14 side. The second envelope E2 corresponds to an end edge portion of the intersection region D on the second busbar 15 side. In the intersection region D, when viewed in the extending direction of the first envelope E1 or the second envelope E2, adjacent electrode fingers overlap each other.

As described above, each of the shapes of the plurality of electrode fingers in a plan view is a shape in which two circular or substantially circular arcs are connected to each other. In a plan view, one circular or substantially circular arc of each of the shapes of the plurality of electrode fingers is each circular or substantially circular arc of a plurality of concentric circles. Therefore, the centers of the circles including the circular or substantially circular arcs in the shapes of the plurality of electrode fingers match each other.

In the present example embodiment, the center of these circles is defined as a fixed point C1. In a plan view, the other circular or substantially circular arc of each of the shapes of the plurality of electrode fingers is also each circular or substantially circular arc of the plurality of concentric circles. The center of these circles is defined as a fixed point C2. As described above, in the present example embodiment, the two fixed points C1 and C2 are defined. The fixed point C1 and the fixed point C2 face each other with the IDT electrode 8 interposed therebetween. However, the shape of the IDT electrode 8 may be a shape in which three or more fixed points are defined.

The shapes of the plurality of electrode fingers in a plan view may include an elliptical or substantially elliptical arc. In this case, the fixed point is a midpoint between two focal points in which the elliptical or substantially elliptical arc is included. In other words, the center of the two focal points is the center of gravity of the two focal points.

Here, an elliptical coefficient of the shapes of the plurality of electrode fingers in a plan view is defined as α2/α1. In the present example embodiment, since the shape of each electrode finger includes two circular or substantially circular4 arcs, two elliptical coefficients α2/α1 can be defined. Specifically, in the shapes of the plurality of electrode fingers, an elliptical coefficient of a circle or an ellipse with a fixed point C1 as a reference is defined as α12/α11, and an elliptical coefficient of a circle or an ellipse with a fixed point C2 as a reference is defined as α22/α21. Both the elliptical coefficients α12/α11 and α22/α21 in the present example embodiment are 1. In a case where the shapes including the arcs in the shapes of the plurality of electrode fingers are ellipses, the elliptical coefficients α12/α11 and α22/α21 are other than 1.

The term α1, that is, α11 and α21 correspond to a dimension along a direction of an axis passing through the intersection region D of the major axis and the minor axis of the ellipse. The term α2, that is, α21 and α22 correspond to a dimension along a direction of an axis that does not pass through the intersection region D of the major axis and the minor axis of the ellipse.

When r1 is an optional constant, the expression of the elliptical coefficient in the XY plane can be represented as (x/α11)²+(y/α12)²=r1². Similarly, when r2 is an optional constant, the expression of the elliptical coefficient in the XY plane can be represented as (x/α21)²+(y/α22)²=r2².

The intersection region D includes a plurality of curved regions. Specifically, in the present example embodiment, the plurality of curved regions include a first curved region W1 and a second curved region W2. The first curved region W1 includes the first envelope E1. The second curved region W2 includes the second envelope E2. In the curved regions, each of the shapes of the plurality of first electrode fingers 16 and the plurality of second electrode fingers 17 in a plan view is a shape of a single circular or substantially circular arc or an elliptical or substantially elliptical arc. A boundary line between the curved regions different from each other corresponds to a line connecting the inflection points of each of the electrode fingers. The boundary line between the first curved region W1 and the second curved region W2 is linear. An extension line of the boundary line passes through the fixed point C1 and the fixed point C2. In the present invention, the intersection region D may include at least two curved regions.

By applying an AC voltage to the IDT electrode 8, an acoustic wave is excited in the intersection region D. The first curved region W1 in the intersection region D has each portion located on an infinite number of straight lines passing through the fixed point C1. In FIG. 3, a straight line M1 is shown as an example of an infinite number of straight lines passing through the fixed point C1 and the first curved region W1. For example, the acoustic wave is excited in a portion located on the straight line M1 in the first curved region W1. The acoustic wave is also excited in each of the portions located on an infinite number of straight lines passing through the fixed point C1 and the first curved region W1, which are not shown in the drawing. That is, the acoustic wave device 1 includes an excitation portion located on the straight line M1 and excitation portions located on an infinite number of straight lines (not shown).

The direction in which the acoustic wave is excited is a direction perpendicular or substantially perpendicular to a direction in which a tangent line of each portion of the electrode finger extends, a direction connecting the shortest distance between adjacent electrode fingers, or a direction parallel or substantially parallel to an electric field vector generated between the electrode fingers. The direction in which the electrode finger extends herein refers to a direction in which the tangent line of a curve connecting each portion of the electrode finger extends. In addition, each portion of the electrode finger can be represented by the center of gravity or an intermediate point between both ends. In an acoustic wave resonator used in the related art shown in FIG. 4, the excitation direction of the acoustic wave is the same in any definition. In a case where the curve is a circular or substantially circular arc centered at the fixed point C, the direction in which the acoustic wave is excited is represented by a direction perpendicular or substantially perpendicular to a direction in which the tangent line of the curve connecting each portion of the electrode fingers extends.

The second curved region W2 in the intersection region D similarly includes an infinite number of excitation portions. In FIG. 3, a straight line M2 is shown as an example of an infinite number of straight lines passing through the fixed point C2 and the second curved region W2. The excitation portion in the second curved region W2 is located on a straight line passing through the fixed point C2.

As described above, the extension lines of the boundary lines of the first curved region W1 and the second curved region W2 pass through the fixed point C1 and the fixed point C2. In the acoustic wave device 1, the straight line including the boundary line and the extension line of the boundary line is defined as a reference line N. An angle between the straight line passing through the excitation portion in the fixed point C1 and the first curved region W1 and the reference line N is defined as an angle θ_{C1}. In FIG. 3, as an example, the angle θ_{C1} of the excitation portion located on the straight line M1 is shown. On the other hand, an angle between the straight line passing through the excitation portion in the fixed point C2 and the second curved region W2 and the reference line N is defined as an angle θ_{C2}. In FIG. 3, as an example, the angle θ_{C2} of the excitation portion located on the straight line M2 is shown. In the present specification, a positive direction of the angle θ_{C1} is a counterclockwise direction when viewed in a plan view. More specifically, a direction from the second busbar 15 side toward the first busbar 14 side is the positive direction. On the other hand, a positive direction of the angle θ_{C2} is a clockwise direction when viewed in a plan view.

In addition, an angle between the straight line passing through the excitation portion of the fixed point C1 and the curved region W1, the excitation direction of the acoustic wave at the intersection of the first electrode finger 16 or the second electrode finger 17, and the reference line N is defined as an excitation angle θ_{C1_prop}. On the other hand, an angle between the straight line passing through the excitation portion of the fixed point C2 and the curved region W2, the excitation direction of the acoustic wave at the intersection of the first electrode finger 16 or the second electrode finger 17, and the reference line N is defined as an excitation angle θ_{C2} prop. Each of the positive and negative directions of the excitation angle θ_{C1_prop} and the excitation angle θ_{C2} prop is the same as the positive and negative directions of the angle θ_{C1} and the angle θ_{C2}.

Here, the angle θ_{C1} in the excitation portion in the first curved region W1 and the excitation angle θ_{C1_prop} match or substantially match each other. Hereinafter, although any one angle of the angle θ_{C1} and the excitation angle θ_{C1_prop}, is discussed, there is no difference between both angles to have an effect that reverses the action and effect. The same applies to the angle θ_{C2} and the excitation angle θ_{C2} prop in the excitation portion in the second curved region W2. When the elliptical coefficient α2/α1 is 1, that is, in a case of being a circle, the angle θ_{C1} and the excitation angle θ_{C1_prop} are equal or substantially equal to each other. The angle θ_{C2} and the excitation angle θ_{C2} prop are equal or substantially equal to each other.

In each curved region, each of the angles between the end edge portion on the first busbar 14 side and the straight line passing through the fixed point, the end edge portion on the second busbar 15 side and the straight line passing through the fixed point, and the reference line N is defined as an intersection angle. An intersection angle in the first curved region W1 is defined as θ_{C1_Ap}, and an intersection angle in the second curved region W2 is defined as θ_{C2_AP}. More specifically, in the present example embodiment, the intersection angle θ_{C1_Ap} in the first curved region W1 is an angle between the straight line passing through the first envelope E1 and the fixed point C1, and the reference line N. In this case, 0≤θ_{C1}<θ_{C1_AP}. On the other hand, the intersection angle θ_{C2_AP} in the second curved region W2 is an angle between a straight line passing through the second envelope E2 and the fixed point C2, and the reference line N. In this case, 0≤θ_{C2}≤θ_{C2_AP}. In the acoustic wave device 1, the intersection angle θ_{C1_Ap} in the first curved region W1 and the intersection angle θ_{C2_AP} in the second curved region W2 are the same or substantially the same as each other. However, the intersection angle θ_{C1_AP} in the first curved region W1 and the intersection angle θ_{C2_AP} in the second curved region W2 may be different from each other.

As a material of the piezoelectric layer 6 of the acoustic wave device 1, a piezoelectric single crystal is used. In the piezoelectric layer 6, the propagation axis is the direction of X propagation. In the present example embodiment, among straight lines passing through the intersection region D and the fixed point C, a straight line extending parallel to the propagation axis is the reference line N. However, the reference line N need not necessarily extend parallel or substantially parallel to the propagation axis.

The propagation axis may be not only the direction of X propagation, but also a direction perpendicular or substantially perpendicular to either the direction of 90° X propagation or the direction in which the electrode finger of the IDT electrode 8 extends. The direction in which the electrode fingers extend herein refers to a direction in which the tangent line of each portion of the electrode fingers extends.

In the excitation portion through which the reference line N passes, the angle θu and the angle θ_{C2}, and the excitation angle θ_{C1_prop} and the excitation angle θ_{C2} prop are about 0°. In each of the excitation portions, the excitation angle θ_{C1_prop} or the excitation angle θ_{C2} prop is different from each other, so that the propagation characteristics of the acoustic waves are different from each other. On the other hand, in the present example embodiment, the duty ratios are different from each other between the plurality of excitation portions such that the resonant frequencies or the anti-resonant frequencies of all of the excitation portions match or substantially match each other. The duty ratios are the same or substantially the same as each other between the excitation portions having the same absolute value of the excitation angle |θ_{C1_prop}| or |θ_{C2_prop|}. Since the IDT electrode 8 is configured as described above, the resonance characteristics are unlikely to deteriorate. However, the duty ratio may be constant.

In the present specification, the fact that one frequency and the other frequency substantially match or substantially match each other means that the absolute value of the difference between both frequencies is equal to or smaller than about 2% of a reference frequency. The reference frequency is a frequency when the excitation angle in each curved region is about 0°. In each curved region, an absolute value of a difference between the highest resonant frequency and the lowest resonant frequency of the main mode is, for example, preferably about 1% or less with respect to the reference frequency. Alternatively, in each curved region, an absolute value of a difference between the highest anti-resonant frequency and the lowest anti-resonant frequency of the main mode is, for example, preferably about 1% or less with respect to the reference frequency.

In the IDT electrode 8 of the acoustic wave device 1, the electrode finger pitch is constant. Therefore, when the wavelength defined by the electrode finger pitch is λ, the wavelength λ in the IDT electrode 8 is constant regardless of the excitation angle θ_{C1_prop} and the excitation angle θ_{C2_prop}. The electrode finger pitch is the center-to-center distance of the first electrode finger 16 and the second electrode finger 17 adjacent to each other. When the electrode finger pitch is p, λ=2p.

In the IDT electrode 8, the first envelope E1 and the first busbar 14 extend parallel or substantially parallel to each other. Similarly, the second envelope E2 and the second busbar 15 extend parallel or substantially parallel to each other. When an angle formed by the reference line N and the busbar is defined as a busbar inclination angle, the busbar inclination angles of the first busbar 14 and the second busbar 15 are the same or substantially the same as each other. However, the busbar inclination angles of the first busbar 14 and the second busbar 15 may be different from each other. In the present specification, a positive direction of the busbar inclination angle is a counterclockwise direction in a plan view.

A pair of reflector 9A and reflector 9B are provided on the piezoelectric layer 6. The reflector 9A and the reflector 9B face each other with the IDT electrode 8 interposed therebetween in an arrangement direction of the plurality of electrode fingers of the IDT electrode 8. The reflector 9A includes a plurality of electrode fingers 9a. The reflector 9B includes a plurality of electrode fingers 9b. In a plan view, each of the shapes of the plurality of electrode fingers 9a of the reflector 9A and the shapes of the plurality of electrode fingers 9b of the reflector 9B is a shape in which two circular or substantially circular arcs are connected to each other. Specifically, these circular or substantially circular arcs correspond to each circular or substantially circular arc of a plurality of concentric circles. More specifically, the center of the circle including one circular or substantially circular arc in the shapes of the plurality of electrode fingers 9a and the plurality of electrode fingers 9b matches the fixed point C1. The center of the circle including the other circular or substantially circular arc matches the fixed point C2. The shape of the electrode finger of each reflector may be a shape of a curve or a straight line different from the shape of the electrode finger of the IDT electrode 8 in the excitation portion. The structural parameters such as the electrode finger pitch or the duty ratio of each reflector may be different from the structural parameters of the electrode finger of the IDT electrode 8 in the excitation portion. The electrode fingers of each reflector may be configured in a pattern different from the shape of the electrode finger of the IDT electrode 8 in the excitation portion.

A feature of the present example embodiment is that the intersection region D includes a plurality of curved regions, and in the intersection region D, as a portion is closer to the first envelope E1 or the second envelope E2, the duty ratio changes to one of a direction in which the duty ratio increases and a direction in which the duty ratio decreases. Specifically, in the present example embodiment, the duty ratio is the maximum in the excitation portion in which the excitation angle θ_{C1_prop} and the excitation angle θ_{C2} prop are about 0°, and the closer the excitation portion is to the first envelope E1 or the second envelope E2, the smaller the duty ratio. As a result, it is possible to reduce or prevent an unnecessary wave outside the pass band and a transverse mode. In the present specification, the outside of the pass band in the acoustic wave device refers to a lower band side than the resonant frequency and a higher band side than the anti-resonant frequency. Details of the above-described advantageous effects will be described below by comparing the present example embodiment with a comparative example.

In the comparative example, as shown in FIG. 4, each of the electrode fingers of the IDT electrode 208, the reflector 209A, and the reflector 209B is linear. In the IDT electrode 208, the intersection region is rectangular or substantially rectangular. In the acoustic wave devices of the first example embodiment and the comparative example, the impedance frequency characteristics, the return loss, and the phase characteristics were compared. The design parameters of the acoustic wave device 1 according to the first example embodiment are as follows. Here, a dimension along a direction connecting a base end portion (base portion) and a tip end portion of the offset electrode is defined as a length of the offset electrode.

Support Substrate 4: material Si, surface orientation (111), ψ at Euler angles (φ, θ, ψ) about 73°
First layer 5a: material SiN, thickness about 0.15 λ
Second layer 5b: material SiO₂, thickness about 0.15 λ
Piezoelectric layer 6: material rotation Y-cut 55° X propagation LiTaO₃, thickness about 0.2 λ
IDT electrode 8: material Al, thickness about 0.05 λ
Number of pairs of electrode fingers of the IDT electrode 8:100 pairs
Elliptical coefficient α12/α11 in the shape of the electrode finger: 1
Elliptical coefficient α22/α21 in the shape of the electrode finger: 1
Intersection Angle θ_{C1}_AP: about 7.5°
Intersection Angle θ_{C2_AP}: about −7.5°
Wavelength λ: about 2 μm
Duty ratio: about 0.5 in the excitation portion in which the excitation angle θ_{C1_prop} and the excitation angle θ_{C1_prop} are about 0°
Busbar inclination angle of the first busbar 14 and the second busbar 15: about 7.5°
Length of the first offset electrode 18 and the second offset electrode 19: about 3.5 λ
Reflector 9A and reflector 9B: Number of pairs of electrode fingers 20 pairs

On the other hand, when a direction in which the plurality of electrode fingers extend is defined as an electrode finger stretching direction and a dimension of the intersection region along the electrode finger stretching direction is defined as an intersection width, the intersection width in the IDT electrode 208 of the acoustic wave device of the comparative example is about 41.5λ. The number of pairs of electrode fingers of the IDT electrode 208 is 60 pairs, and the number of pairs of electrode fingers of each of the reflector 209A and the reflector 209B is 20 pairs. In the IDT electrode 208, the duty ratio is about 0.5.

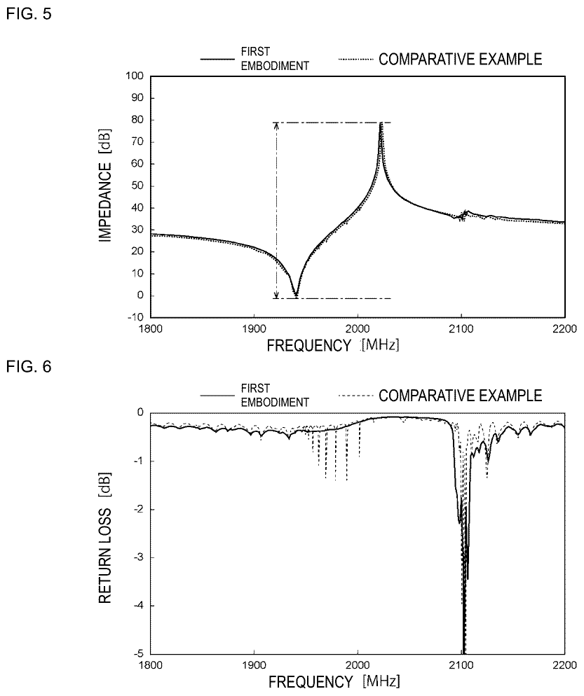

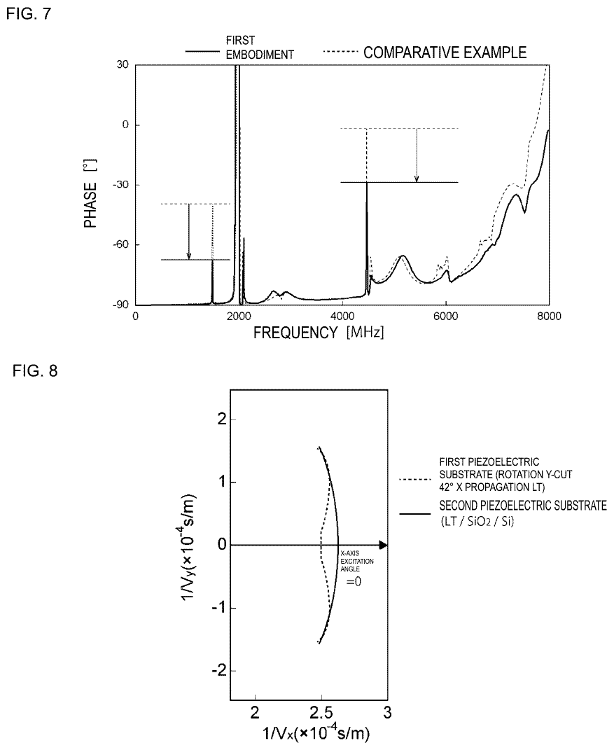

FIG. 5 is a graph showing the impedance frequency characteristics in the first example embodiment and the comparative example. FIG. 6 is a graph showing a return loss in the first example embodiment and the comparative example. FIG. 7 is a graph showing phase characteristics in the first example embodiment and the comparative example.

As shown in FIGS. 5 and 6, in the comparative example, a plurality of ripples are generated between the resonant frequency and the anti-resonant frequency. Specifically, the plurality of ripples are generated in the vicinity of about 1950 MHz to about 2000 MHz, for example. These ripples are caused by the transverse mode. On the other hand, it can be seen that the ripples caused by the transverse mode are reduced or prevented in the first example embodiment. Furthermore, as shown in FIG. 7, it can be seen that the unnecessary wave outside the pass band is reduced or prevented in the first example embodiment as compared with the comparative example. Specifically, in the first example embodiment, the unnecessary wave is reduced or prevented on both the lower band side of the resonant frequency and the higher band side of the anti-resonant frequency. As described above, in the first example embodiment, it is possible to reduce or prevent the unnecessary wave outside the pass band and to reduce or prevent the transverse mode.

In example embodiments of the present invention, the above-described advantageous effects are obtained by utilizing the fact that the propagation characteristics of the acoustic wave are different from each other in each of the excitation portions. Details will be described below.

The phase velocity of the acoustic wave has dependence on the excitation angle in each curved region and exhibits unique characteristics depending on the configuration of the substrate. The reciprocal of the phase velocity corresponds to the reverse-velocity surface. Therefore, the relationship between the excitation angle θ_{C1_prop}, the excitation angle θ_{C2} prop, and the phase velocity is equal or substantially equal to the reverse-velocity surface of the piezoelectric substrate. Therefore, examples of reverse-velocity surfaces of the piezoelectric substrates having different layer configurations will be described. The one piezoelectric substrate is, for example, a substrate including only LiTaO₃ (LT) of the rotation Y-cut 42° X propagation. This substrate is defined as a first piezoelectric substrate. The other piezoelectric substrate is a bonded substrate of a piezoelectric layer and a support substrate. This substrate is defined as a second piezoelectric substrate. More specifically, the second piezoelectric substrate is, for example, a substrate in which a silicon substrate having a surface orientation of (100), a silicon oxide film, and a lithium tantalate layer are laminated in this order.

The shape of the unevenness of the reverse-velocity surface does not change even when the surface orientation of the silicon substrate is another surface orientation such as (110) or (111).

FIG. 8 is a graph showing reverse-velocity surfaces of acoustic waves propagating in the first piezoelectric substrate and the second piezoelectric substrate.

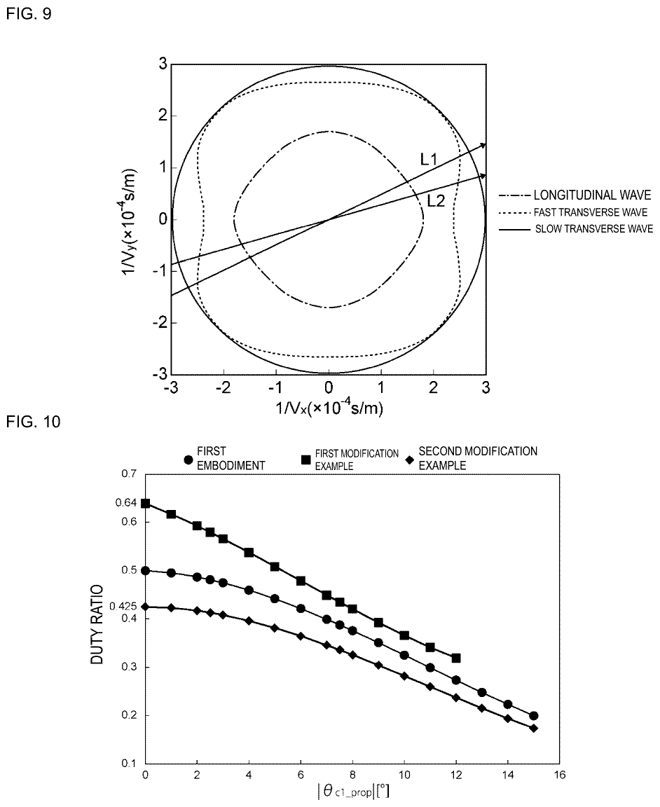

The x-axis shown in FIG. 8 corresponds to the result when the x-axis is parallel or substantially parallel to the propagation axis. That is, the x-axis corresponds to a result when the excitation angle θ_{C1_prop} and the excitation angle θ_{C2} prop are about 0°. The reverse-velocity surfaces of the first piezoelectric substrate and the second piezoelectric substrate are both line-symmetrical with the x-axis as a symmetry axis. The reverse-velocity surface in the first piezoelectric substrate has a recessed shape. On the other hand, the reverse-velocity surface in the second piezoelectric substrate has a projected shape. As described above, it can be seen that dependence on the excitation angle θ_{C1_prop} and the excitation angle θ_{C1_prop} of the acoustic wave propagating on the substrate varies depending on the configuration of the substrate. Furthermore, in a case where the modes of acoustic waves are different from each other, dependence on the excitation angle θ_{C1_prop} and the excitation angle θ_{C1_prop} on the same substrate are different from each other. This is shown in FIG. 9.

FIG. 9 is a graph showing reverse-velocity surfaces of a longitudinal wave, a fast transversal wave, and a slow transversal wave in the first piezoelectric substrate.

As shown in FIG. 9, the reverse-velocity surfaces of a longitudinal wave, a fast transversal wave, and a slow transversal wave, which are three modes of acoustic waves, are different from each other. Each of the portions passing through the arrows L1 and L2 in FIG. 9 corresponds to an example of a result in a case where the excitation angle θ_{C1_prop} and the excitation angle θ_{C2_prop} are other than 0°. An interval between the reverse-velocity surfaces of the slow transversal wave and the fast transversal wave in the portion passing through the arrow L1 and an interval between the reverse-velocity surfaces of the slow transversal wave and the fast transversal wave in the portion passing through the arrow L2 are different from each other. Similarly, an interval between the reverse-velocity surfaces of the fast transversal wave and the longitudinal wave in the portion passing through the arrow L1 and an interval between the reverse-velocity surfaces of the fast transversal wave and the longitudinal wave in the portion passing through the arrow L2 are different from each other. That is, in each of the curved regions, the intervals between the reverse-velocity surfaces of different modes are different in the excitation portions having different excitation angles. The same applies to a relationship between the main mode used in the acoustic wave device and the unnecessary wave.

In this case, in the acoustic wave device 1 according to the first example embodiment, the resonant frequencies or the anti-resonant frequencies of the main mode match or substantially match each other in all of the excitation portions. Therefore, in the different excitation portions, the frequencies of the unnecessary waves are different from each other. As a result, each of the unnecessary wave outside the pass band and the transverse mode is dispersed. Therefore, it is possible to reduce or prevent the unnecessary wave outside the pass band and the transverse mode.

In the first example embodiment, since the resonant frequencies or the anti-resonant frequencies in each of the excitation portions match or substantially match each other, the main mode is suitably excited.

For example, as shown in FIG. 5, the impedance ratio in the first example embodiment is the same or substantially the same as the impedance ratio in the comparative example. As described above, the deterioration of the resonance characteristics can be reduced or prevented.

In addition, as shown in FIG. 3, in the first example embodiment, the intersection region D includes the first curved region W1 and the second curved region W2. As a result, the intersection angle can be effectively increased at any position of the acoustic wave device 1. More specifically, each of the electrode fingers includes a portion located in the first curved region W1 and a portion located in the second curved region W2. Therefore, the intersection angle in the portion in which each electrode finger is located corresponds to the sum of the intersection angle θ_{C1_Ap} in the first curved region W1 and the intersection angle θ_{C2_AP} in the second curved region W2. Therefore, the range of the excitation angle is wide at any position of the intersection region D. As a result, it is possible to effectively disperse the unnecessary wave outside the pass band and the transverse mode.

Hereinafter, the fact that the resonant frequencies in the main mode match or substantially match each other will be described in detail. As described above, the phase velocity corresponds to the reciprocal of the reverse-velocity surface. Therefore, the relationship between the excitation angle θ_{C1_prop}, the excitation angle θ_{C2_prop}, and the phase velocity is substantially equal to the reverse-velocity surface of the piezoelectric substrate in the XY plane as shown in FIG. 9. That is, it can be said that the function representing the curved shape of the electrode finger is determined by the shape of the reverse-velocity surface of the piezoelectric substrate in the XY plane. The phase velocity of the acoustic wave has dependence on the excitation angle θ_{C1_prop} and the excitation angle θ_{C2_prop}.

However, when the shape of the electrode finger is simply made to be curved, the impedance frequency characteristics are obtained by superimposing the characteristics in which the resonant frequencies at each of the excitation angles θ_{C1_prop} and θ_{C2_prop} are significantly different from each other.

Therefore, the impedance frequency characteristics significantly deteriorate. Therefore, in the first example embodiment, the duty ratio that affects the frequency is changed according to the excitation angle θ_{C1_prop} and the excitation angle θ_{C2_prop}. As a result, the frequencies of the acoustic wave excited at each of the excitation angle θ_{C1_prop} and the excitation angle θ_{C2_prop} can match or substantially match each other. Therefore, in each of the excitation portions, the resonant frequencies can match or substantially match each other. In each of the excitation portions, the anti-resonant frequencies can also match or substantially match each other. Therefore, the impedance frequency characteristics are obtained in which the resonant frequencies or the anti-resonant frequencies match or substantially match each other.

In the first example embodiment, a relationship between the excitation angle θ_{C1_prop} and the duty ratio is described in FIG. 10. An example in which the maximum value of the duty ratio is different from that of the first example embodiment is also described as a first modified example and a second modified example of the first example embodiment.

FIG. 10 is a graph showing a relationship between an absolute value of an excitation angle |θ_{C1_prop}| and a duty ratio of the IDT electrode in the first example embodiment, the first modified example, and the second modified example.

In the first example embodiment, in a case where the excitation angle θ_{C1_prop} is 0°, the duty ratio is at a maximum value. In the first example embodiment, when the excitation angle θ_{C1_prop} is about 0°, the duty ratio is about 0.5. The larger the absolute value of the excitation angle |θ_{C1_prop}|, the smaller the duty ratio. As a result, the resonant frequencies or the anti-resonant frequencies match or substantially match each other in all of the excitation portions in the first curved region.

Even in the first modified example and the second modified example, the larger the absolute value of the excitation angle |θ_{C1_prop}|, the smaller the duty ratio. In the first modified example, the duty ratio is, for example, about 0.64 when the excitation angle θ_{C1_prop} is about 0°. In the second modified example, the duty ratio is, for example, about 0.425 when the excitation angle θ_{C1_prop} is about 0°. In the first modified example and the second modified example, the resonant frequencies or the anti-resonant frequencies match or substantially match each other in all of the excitation portions in the first curved region. In the first example embodiment, the first modified example, and the second modified example, the relationship between the absolute value of the excitation angle |θ_{C2_prop|} in the second curved region and the duty ratio is also the same as or similar to the relationship shown in FIG. 10. Therefore, even in all of the excitation portions in the second curved region, the resonant frequencies or the anti-resonant frequencies match or substantially match each other.

In addition, in the first modified example and the second modified example, the configuration is the same or substantially the same as that of the first example embodiment except for the duty ratio. Therefore, it is possible to reduce or prevent the unnecessary wave outside the pass band and the transverse mode.

Incidentally, a semiconductor lithography method is used for forming the IDT electrode 8, for example. When a resist and a metal wire pattern are formed using the semiconductor lithography method, and the duty ratio is, for example, less than about 0.2 or more than about 0.8, it is not easy to form a pattern, and it is difficult to perform stable pattern processing with small manufacturing variations. According to FIG. 10, the larger the duty ratio when the excitation angle θ_{C1_prop} is about 0°, the larger the duty ratio when the absolute value of the excitation angle |θ_{C1_prop}| is increased. That is, as the duty ratio when θ_{C1_prop} is about 0° is large, a curve pattern in which the absolute value of the excitation angle |θ_{C1_prop}| is large can be formed. In the curve pattern in a range where the absolute value of the excitation angle |θ_{C1_prop}| is large, the advantageous effects of reducing or preventing the unnecessary wave is further improved. From these facts, the duty ratio of the electrode fingers of the IDT electrode 8 is, for example, preferably in a range of about 0.2 or more and about 0.8 or less, and more preferably in a range of about 0.25 or more and about 0.75 or less. In addition, for example, when θ_{C1_prop} is about 0°, it is preferable that the duty ratio is about 0.5 rather than about 0.425, and it is more preferable that the duty ratio is about 0.64 rather than about 0.5.

The relationship between the duty ratio and the frequency of each mode varies depending on the reverse-velocity surface of the piezoelectric substrate. Therefore, depending on the configuration of the piezoelectric substrate or the configuration on the piezoelectric substrate, when the larger the absolute values of the excitation angles |θ_{C1_prop}| and |θ_{C2_prop}|, the larger the duty ratio, the resonant frequencies or the anti-resonant frequencies may match or substantially match each other in all of the excitation portions. Examples thereof include an acoustic wave device in which an IDT electrode provided on substrate including only LiNbO₃ having a rotation Y-cut-4° X propagation is embedded in a SiO₂ film having a thick thickness.

Alternatively, in the excitation portion in which the reference line N passes and the excitation angle θ_{C1} prop and the excitation angle θ_{C2_prop} are about 0°, the duty ratio is not necessarily maximum or minimum.

In the first example embodiment, the loss at the resonant frequency or less can be reduced. This effect advantageous will be described by comparing the first example embodiment and the reference example.

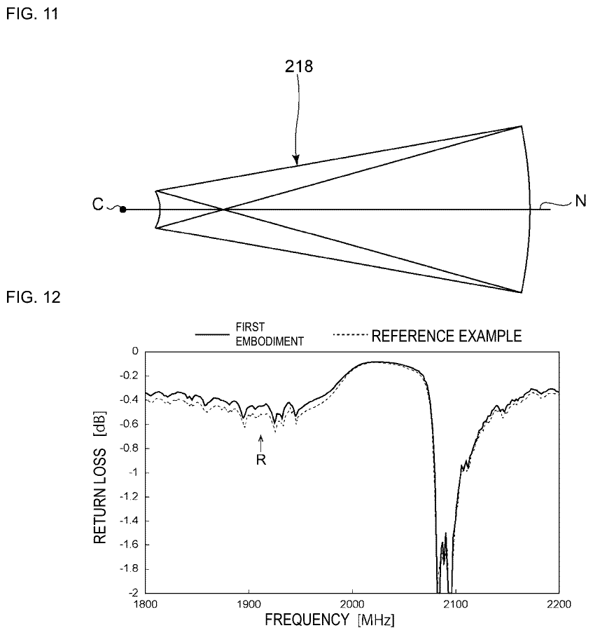

In the reference example, as shown schematically in FIG. 11, the shape of the IDT electrode 218 in a plan view is substantially fan-shaped, and is line-symmetrical with the reference line N as a symmetry axis. The shape of each of the electrode fingers of the reference example in a plan view is a single circular or substantially circular arc shape. Therefore, there is only one fixed point in the reference example. The reference line N in the reference example passes through the center and the fixed point in the intersection region.

The design parameters of the acoustic wave device 1 according to the first example embodiment related to the comparison are the same as or similar to the design parameters of the acoustic wave device 1 related to the comparison of FIGS. 5 to 7 except for the following points.

Number of pairs of electrode fingers of the IDT electrode 8:90 pairs
Intersection Angle θ_{C1_AP}: about 10°
Intersection Angle θ_{C2_AP}: about 10°
Duty ratio: about 0.64 in the excitation portion in which the excitation angle θ_{C1_prop} and the excitation angle θ_{C1_prop} are about 0°

The design parameters of the reference example were also the same as or similar to those of the acoustic wave device 1 according to the first example embodiment related to the comparison. In the reference example, the intersection angle θ_{C1_Ap} corresponds to an angle between the reference line N and an end edge portion of one busbar side in the intersection region. The intersection angle θ_{C2_AP} corresponds to an angle between the reference line N and an end edge portion of the other busbar side in the intersection region. Even in the reference example, the duty ratio is adjusted such that the resonant frequencies or the anti-resonant frequencies match or substantially match each other in all of the excitation portions in the intersection region.

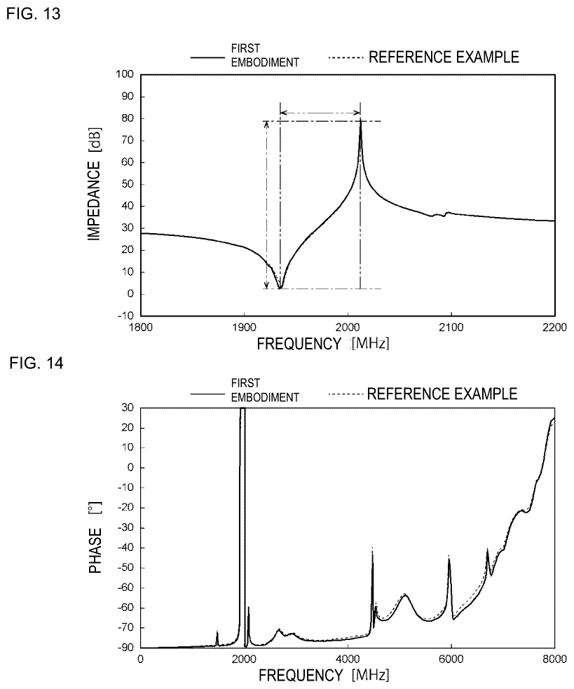

FIG. 12 is a graph showing a return loss in the first example embodiment and the reference example. FIG. 13 is a graph showing the impedance frequency characteristics in the first example embodiment and the reference example. FIG. 14 is a graph showing phase characteristics in the first example embodiment and the reference example.

As shown in FIG. 12, at least in the vicinity of the frequency indicated by the arrow R, an absolute value of the return loss in the first example embodiment is smaller than an absolute value of the return loss in the reference example. The resonant frequency of the acoustic wave device of the first example embodiment and the reference example is approximately 1940 MHZ, and the anti-resonant frequency is approximately 2010 MHz. As described above, it can be seen that the loss at the resonant frequency or less can be reduced in the first example embodiment. Furthermore, in the first example embodiment, the loss can be reduced in the band between the resonant frequency and the anti-resonant frequency.

As shown in FIG. 13, the impedance ratio in the first example embodiment is the same or substantially the same as the impedance ratio in the reference example. Furthermore, the fractional band width in the first example embodiment is also equivalent to the fractional band width in the reference example. The fractional band width is represented by |fa−fr|/fr when the resonant frequency is denoted by fr and the anti-resonant frequency is denoted by fa. As shown in FIG. 14, in both of the first example embodiment and the reference example, it is possible to reduce or prevent the unnecessary wave outside the pass band.

Returning to FIG. 1, each of the shapes of the plurality of first offset electrodes 18 in the first example embodiment is a shape corresponding to each circular or substantially circular arc of the plurality of concentric circles. The center of the circle including the circular or substantially circular arc in the shape of the plurality of first offset electrodes 18 matches the fixed point C1 shown in FIG. 3. In a case where the shapes of the plurality of electrode fingers in a plan view in the first curved region W1 are the shapes of the elliptical or substantially elliptical arc, the shape of the plurality of first offset electrodes 18 may be the shape of the elliptical or substantially elliptical arc included in the ellipse with the fixed point C1 as the center of gravity. In the IDT electrode 8, the duty ratio is also changed in the region between the first curved region W1 and the first busbar 14, the same as or similar to the first curved region W1. More specifically, in the first example embodiment, in the region between the first busbar 14 and the intersection region D, the closer to the first busbar 14, the smaller the duty ratio.

Similarly, each of the shapes of the plurality of second offset electrodes 19 is also a shape corresponding to each of the circular or substantially circular arcs of the plurality of concentric circles. The center of the circle including the circular or substantially circular arc in the shape of the plurality of second offset electrodes 19 matches the fixed point C2.

In a case where the shapes of the plurality of electrode fingers in a plan view in the second curved region W2 are the shapes of the elliptical or substantially elliptical arc, the shape of the plurality of second offset electrodes 19 may be the shape of the elliptical or substantially elliptical arc included in the ellipse with the fixed point C2 as the center of gravity. In the IDT electrode 8, the duty ratio is also changed in the region between the second curved region W2 and the second busbar 15, the same as or similar to the second curved region W2. More specifically, in the first example embodiment, in the region between the second busbar 15 and the intersection region D, the closer to the second busbar 15, the smaller the duty ratio. The shapes of the plurality of first offset electrodes 18 and the plurality of second offset electrodes 19 are not limited to the above-described shapes. For example, in the region between the first busbar 14 and the intersection region D, the closer to the first busbar 14, the larger the duty ratio may be. In the region between the second busbar 15 and the intersection region D, the closer to the second busbar 15, the larger the duty ratio may be. Alternatively, the offset electrode need not necessarily be provided. Even in this case, the unnecessary wave can be reduced or prevented. Furthermore, the shapes of the first electrode finger 16 and the second electrode finger 17 are not particularly limited in regions other than the intersection region D.

As described above, the tip end portion of the second electrode finger 17 and the tip end portion of the first offset electrode 18 face each other with the gap g1 interposed therebetween. The size of the gap g1 is a distance between the tip end portion of the second electrode finger 17 and the tip end portion of the first offset electrode 18. Similarly, the size of the gap g2 is a distance between the tip end portion of the first electrode finger 16 and the tip end portion of the second offset electrode 19. The sizes of the gap g1 and the gap g2 are, for example, preferably about 1λ or less and more desirably about 0.5λ or less. When the gap g1 is larger than about 0.5λ, there is a tendency for the acoustic wave to easily leak from the intersection region D in a direction toward the first busbar 14. The same applies to a case where the gap g2 is larger than about 0.5λ. When the sizes of the gap g1 and the gap g2 exceed about 1λ, the amount of leakage of the main mode increases, and the loss may be non-negligible.

In addition, the lengths of the first offset electrode 18 and the second offset electrode 19 are, for example, preferably about 1λ or more and more desirably about 1.3λ or more.

When the length of the first offset electrode 18 is shorter than about 1.3λ, there is a tendency for the acoustic wave to easily leak from the intersection region D in a direction toward the first busbar 14. The same applies to a case where the length of the second offset electrode 19 is shorter than about 1.3λ. When the lengths of the first offset electrode 18 and the second offset electrode 19 are shorter than about 1λ, the amount of leakage of the main mode increases, and the loss may be non-negligible.

Incidentally, as shown in FIG. 2, in the first example embodiment, the piezoelectric substrate 2 is a laminated substrate including the support substrate 4, the first layer 5a and the second layer 5b of the intermediate layer 5, and the piezoelectric layer 6. More specifically, the first layer 5a in the first example embodiment is a high acoustic velocity film. The high acoustic velocity film is a layer having a relatively high acoustic velocity. More specifically, the acoustic velocity of the bulk wave propagating through the high acoustic velocity film is higher than the acoustic velocity of the acoustic wave propagating through the piezoelectric layer 6. On the other hand, the second layer 5b is a low acoustic velocity film. The low acoustic velocity film is a film having a relatively low acoustic velocity. More specifically, the acoustic velocity of the bulk wave propagating through the low acoustic velocity film is lower than the acoustic velocity of the bulk wave propagating through the piezoelectric layer 6.

In the first example embodiment, in the piezoelectric substrate 2, the high acoustic velocity film, the low acoustic velocity film, and the piezoelectric layer 6 are laminated in this order. As a result, the energy of the acoustic wave can be effectively confined to the piezoelectric layer 6 side.

As the material of the high acoustic velocity film, for example, a media including the following material as a main component, such as silicon, aluminum oxide, silicon carbide, silicon nitride, silicon oxynitride, sapphire, lithium tantalate, lithium niobate, quartz, alumina, zirconia, cordierite, mullite, steatite, forsterite, magnesia, a diamond-like carbon (DLC) film, diamond, spinel, or sialon can be used.

As the material of the low acoustic velocity film, for example, glass, silicon oxide, silicon oxynitride, lithium oxide, tantalum pentoxide, or a material including a compound in which fluorine, carbon, or boron is added to silicon oxide as a main component can be used.

As the material of the piezoelectric layer 6, for example, lithium tantalate, lithium niobate, zinc oxide, aluminum nitride, quartz, or lead zirconate titanate (PZT) can also be used. As the material of the piezoelectric layer 6, for example, it is preferable to use lithium tantalate or lithium niobate.

As a material of the support substrate 4, for example, a piezoelectric body such as aluminum nitride, lithium tantalate, lithium niobate, or quartz, ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, a semiconductor such as silicon, or a material including the above-described material as a main component can be used. The spinel exemplified as the material of the support substrate 4 and the high acoustic velocity film includes an aluminum compound including one or more of Mg, Fe, Zn, and Mn, or oxygen. Examples of the above-described spinel can include MgAl:O₄, FeAl:O₄, ZnAl:O₄, or MnAl:O₄. Silicon is preferably used as the material of the support substrate 4.

In the present specification, the main component means a component whose occupied ratio exceeds 50% by weight. The material of the main component may exist in any one state of single crystal, polycrystal, and amorphous, or in a mixed state thereof.

The relationship between the acoustic velocities in the first layer 5a and the second layer 5b in the intermediate layer 5 is not limited to the above-described relationship. Furthermore, the layer configuration of the piezoelectric substrate 2 is not limited to the above-described configuration. Hereinafter, a third modified example and a fourth modified example of the first example embodiment which are different from the first example embodiment only in the configuration of the piezoelectric substrate 2 will be described. In the third modified example and the fourth modified example, it is possible to reduce or prevent the unnecessary wave outside the pass band and the transverse mode, the same as or similar to the first example embodiment. Furthermore, the energy of the acoustic wave can be effectively confined to the piezoelectric layer 6 side.

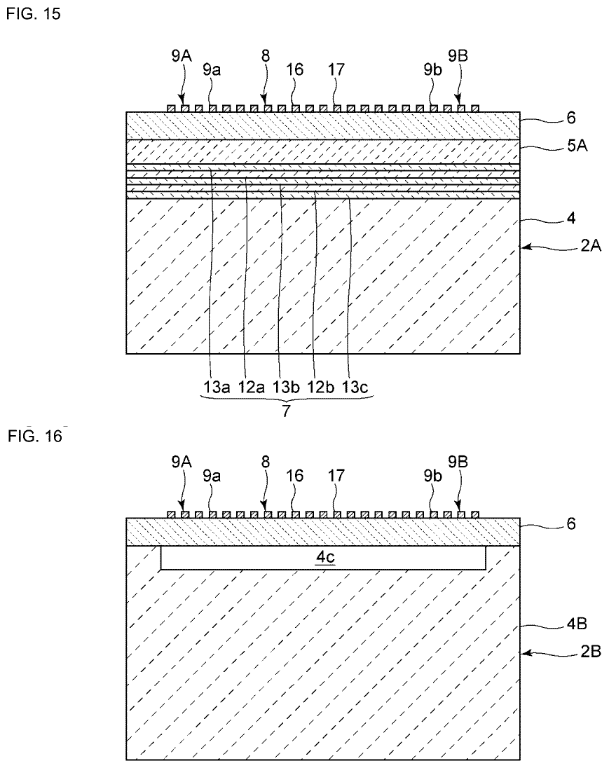

In the third modified example shown in FIG. 15, a piezoelectric substrate 2A includes the support substrate 4, an acoustic reflection film 7, an intermediate layer 5A, and the piezoelectric layer 6. The acoustic reflection film 7 is provided on the support substrate 4. The intermediate layer 5A is provided on the acoustic reflection film 7. The piezoelectric layer 6 is provided on the intermediate layer 5A. The intermediate layer 5A is the low acoustic velocity film.

The acoustic reflection film 7 is a multilayer body including a plurality of acoustic impedance layers. Specifically, the acoustic reflection film 7 includes a plurality of low acoustic impedance layers and a plurality of high acoustic impedance layers. The high acoustic impedance layer is a layer having a relatively high acoustic impedance. More specifically, the plurality of high acoustic impedance layers of the acoustic reflection film 7 are a high acoustic impedance layer 13a, a high acoustic impedance layer 13b, and a high acoustic impedance layer 13c. On the other hand, the low acoustic impedance layer is a layer having a relatively low acoustic impedance. More specifically, the plurality of low acoustic impedance layers of the acoustic reflection film 7 are a low acoustic impedance layer 12a and a low acoustic impedance layer 12b. The low acoustic impedance layer and the high acoustic impedance layer are alternately laminated. The high acoustic impedance layer 13a is a layer located closest to the piezoelectric layer 6 side in the acoustic reflection film 7.

The acoustic reflection film 7 includes two low acoustic impedance layers and three high acoustic impedance layers. However, the acoustic reflection film 7 may include at least one low acoustic impedance layer and at least one high acoustic impedance layer.

As a material of the low acoustic impedance layer, for example, silicon oxide or aluminum can be used. As a material of the high acoustic impedance layer, for example, metal such as platinum or tungsten, or a dielectric such as aluminum nitride or silicon nitride can be used. The material of the intermediate layer 5A may be the same as the material of the low acoustic impedance layer.

In the fourth modified example shown in FIG. 16, a piezoelectric substrate 2B includes a support substrate 4B and the piezoelectric layer 6. The piezoelectric layer 6 is directly provided on the support substrate 4B. More specifically, the support substrate 4B includes a recessed portion 4c. The piezoelectric layer 6 is provided on the support substrate 4B so as to cover the recessed portion 4c. As a result, a hollow portion is provided in the piezoelectric substrate 2B. The hollow portion overlaps at least a portion of the IDT electrode 8 in a plan view.

In the first example embodiment, the resonant frequencies or the anti-resonant frequencies of all of the excitation portions match or substantially match each other by changing the duty ratio according to the excitation angle in each curved region. However, the present invention is not limited thereto. As the excitation portion is closer to the first envelope E1 or the second envelope E2, a value of at least one of the duty ratio, the electrode finger pitch, and the thicknesses of the plurality of first electrode fingers 16 and the plurality of second electrode fingers 17 may change in one of the direction in which the value increases and the direction in which the value decreases. Alternatively, a parameter such as a thickness of the intermediate layer in the piezoelectric substrate, which affects the frequency, may be changed according to the excitation angle in each of the curved regions. In a case where a dielectric film is provided on the piezoelectric substrate to cover the IDT electrode, the thickness of the dielectric film may be changed according to the excitation angle in each of the curved regions. A plurality of the parameters among the above parameters may be changed according to the excitation angle in each of the curved regions. Even in these cases, the resonant frequencies or the anti-resonant frequencies can match or substantially match each other in all of the excitation portions.

The duty ratio including the offset electrode, the center-to-center distance between the offset electrode and the electrode finger, and the thickness of the offset electrode may also be changed, the same as or similar to the parameters of the electrode finger in the excitation portion.

Hereinafter, an example in which the parameter other than the duty ratio is changed according to the excitation angle in each curved region will be described. In each of the following examples, since the shape of the IDT electrode is different from that of the first example embodiment, the shape of the reflector is also different from that of the first example embodiment.

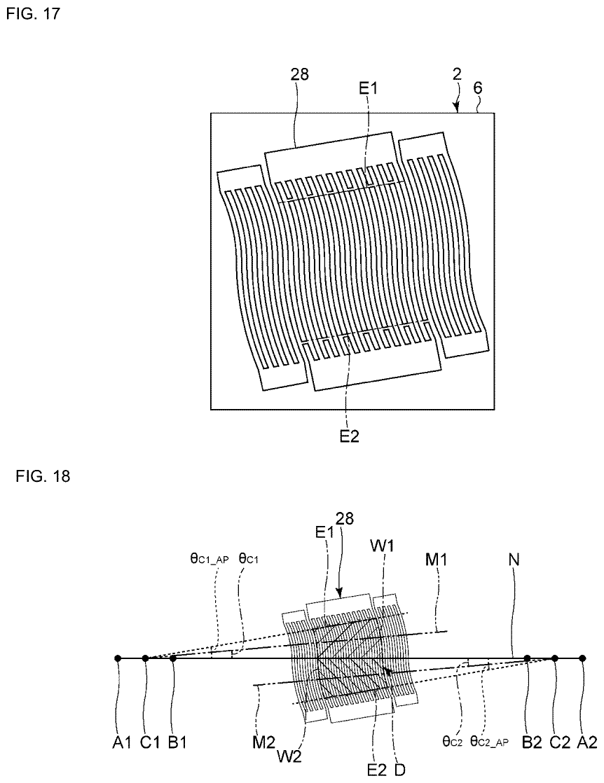

FIG. 17 is a schematic plan view of an acoustic wave device according to a second example embodiment of the present invention.

The present example embodiment is different from the first example embodiment in that the shapes of the plurality of electrode fingers in a plan view are the shapes of the elliptical or substantially elliptical arc. The present example embodiment is different from the first example embodiment in that the duty ratio is constant and the electrode finger pitch is not constant in the IDT electrode 28. Except for the above points, the acoustic wave device according to the present example embodiment has the same or substantially the same configuration as the acoustic wave device 1 according to the first example embodiment.

The shapes of the plurality of electrode fingers in a plan view are the shapes in which two elliptical or substantially elliptical arcs are connected to each other. As shown in FIG. 18, even in the present example embodiment, the intersection region D has the first curved region W1 and the second curved region W2. In the first curved region W1, each of the shapes of the plurality of electrode fingers in a plan view a shape corresponding to each of the elliptical or substantially elliptical arcs of a plurality of ellipses whose centers of gravity are located at the same or substantially the same position. More specifically, the center of gravity is a midpoint between a focal point A1 and a focal point B1 shown in FIG. 18. The center of gravity is the fixed point C1. The same applies to the second curved region W2. The center of gravity of a focal point A2 and a focal point B2 is a fixed point C2.

In the present example embodiment, α12/α11 and α2²/α21 as the elliptical coefficients α1/α2 of the shapes of the plurality of electrode fingers in a plan view satisfy α12/α11<1 and 2²/α21 <1. More specifically, for example, α12/α11=α2²/α21=about 0.72. However, the elliptical coefficients α12/α11 and α2²/α21 are not limited to the above-described elliptical coefficients.

As described above, in the IDT electrode 28, the duty ratio is constant. Specifically, for example, the duty ratio is about 0.5. In the first curved region W1, the larger the absolute value of the excitation angle |θ_{C1_prop}|, the narrower the electrode finger pitch. In the second curved region W2, the larger the absolute value of the excitation angle |θ_{C2_prop}|, the narrower the electrode finger pitch. As a result, the resonant frequencies or the anti-resonant frequencies match or substantially match each other in all of the excitation portions. Hereinafter, a relationship between the absolute value of the excitation angle |θ_{C1_prop}| and the electrode finger pitch will be specifically described. Here, the electrode finger pitch in the excitation portion in which the excitation angle θ_{C1} prop is about 0° is denoted by p0, the electrode finger pitch of any portion is denoted by p1, and {(p1−p0)/p0}×100 [%] is defined as the change rate of the electrode finger pitch Δpitch [%].

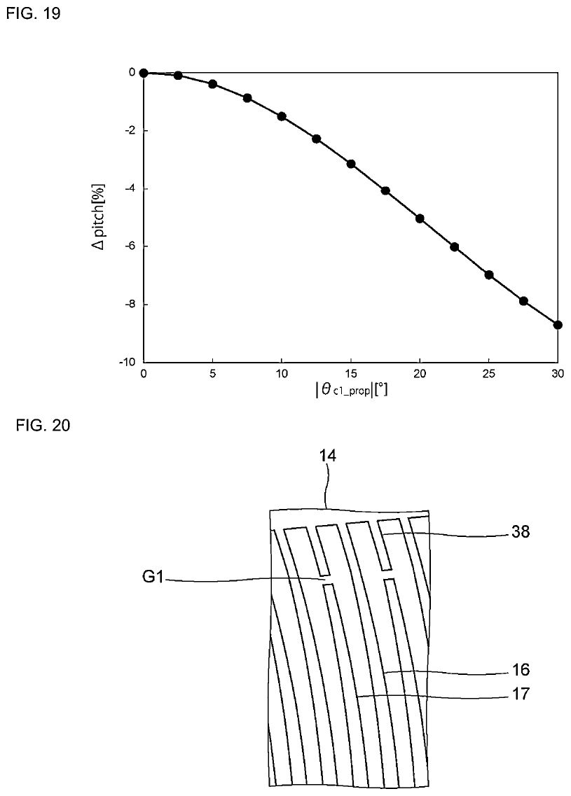

FIG. 19 is a graph showing a relationship between an absolute value of an excitation angle |θ_{C1_prop}| and a rate of change Δpitch of an electrode finger pitch of the IDT electrode in the second example embodiment.

As shown in FIG. 19, in the present example embodiment, in the excitation portion in which the excitation angle θ_{C1_prop} in the IDT electrode 28 is about 0°, the Δpitch is about 0%.

The larger the absolute value of the excitation angle ↑θ_{C1_prop}|, the larger Δpitch in the negative direction. That is, the larger the absolute value of the excitation angle |θ_{C1_prop}|, the narrower the electrode finger pitch. In the present example embodiment, the relationship between the absolute value of the excitation angle |θ_{C2_prop|} and the Δpitch in the second curved region W2 is also the same as or similar to the relationship shown in FIG. 19. As a result, the resonant frequencies or the anti-resonant frequencies match or substantially match each other in all of the excitation portions in the first curved region W1 and the second curved region W2. Similar to the first example embodiment, it is possible to disperse the unnecessary wave outside the pass band and the transverse mode, and to reduce or prevent the unnecessary wave outside the pass band and the transverse mode.

Furthermore, an example of the design parameters of the acoustic wave device of the present example embodiment will be described below.
Elliptical coefficient α12/α11 in the shape of the electrode finger: about 0.72
Elliptical coefficient α2²/α21 in the shape of the electrode finger: about 0.72
Intersection Angle θ_{C1}_AP: about 7.5°
Intersection Angle θ_{C2_AP}: about −7.5°
Longest wavelength λ: about 2 μm
Electrode finger pitch: about 1 μm in the excitation portion in which the excitation angle θ_{C1_prop} and the excitation angle θ_{C1_prop} are about 0°

Duty Ratio: about 0.5

Busbar inclination angle of the first busbar and the second busbar: about 7.5°

Length of the first offset electrode and the second offset electrode: about 3.5 λ

The relationship between the electrode finger pitch and the frequency of each mode varies depending on the reverse-velocity surface of the piezoelectric substrate. Therefore, depending on the configuration of the piezoelectric substrate or the configuration on the piezoelectric substrate, when the larger the absolute values of the excitation angles |θ_{C1_prop}| and |θ_{C2}_prop|, the wider the electrode finger pitch, the resonant frequencies or the anti-resonant frequencies may match or substantially match each other in all of the excitation portions. Examples thereof include an acoustic wave device in which an IDT electrode provided on a substrate including only LiNbO₃ having a rotation Y-cut −4° X propagation is embedded in a SiO: film having a thick thickness. Alternatively, in the excitation portion in which the reference line N passes and the excitation angle θ_{C1_prop} and the excitation angle θ_{C2} prop are about 0°, the value of the electrode finger pitch is not necessarily maximum or minimum.

FIG. 20 is a schematic plan view showing the vicinity of a gap on a first busbar side of an IDT electrode in a third example embodiment of the present invention.

The present example embodiment is different from the first example embodiment in that the duty ratio is constant in the region between the intersection region and the first busbar 14, and the region between the intersection region and the second busbar. Except for the above points, the acoustic wave device according to the present example embodiment has the same or substantially the same configuration as the acoustic wave device 1 according to the first example embodiment.

The duty ratio in the region between the intersection region and the first busbar 14 is the same or substantially the same as the duty ratio in the portion in which the tip end portions of the plurality of second electrode fingers 17 are arranged. The width of the plurality of first offset electrodes 38 is constant. The widths of the plurality of first electrode fingers 16 are also constant in the region in the outer side portion of the intersection region. More specifically, the width of the plurality of first offset electrodes 38 is the same or substantially the same as the width of the tip end portions of the plurality of second electrode fingers 17. The widths of the plurality of first electrode fingers 16 are the same or substantially the same as the widths of the plurality of first offset electrodes 38 in the region in the outer side portion of the intersection region. The shapes of the plurality of first offset electrodes 38 in a plan view are curved. The shapes of the plurality of first electrode fingers 16 in the region in the outer side portion of the intersection region in a plan view are also curved.

Although not shown, the duty ratio in the region between the intersection region and the second busbar is the same or substantially the same as the duty ratio in the portion in which tip end portions of the plurality of first electrode fingers 16 are arranged. The width of the plurality of second offset electrodes is the same or substantially the same as the width of the tip end portions of the plurality of first electrode fingers 16 and are constant. The width of the plurality of second electrode fingers 17 is the same or substantially the same as the width of the plurality of second offset electrodes in the region in the outer side portion of the intersection region. The shapes of the plurality of second offset electrodes in a plan view are curved. The shapes of the plurality of second electrode fingers 17 in the region in the outer side portion of the intersection region in a plan view are also curved.

In the present example embodiment, the widths of the plurality of first offset electrodes 38 and the plurality of first electrode fingers 16 are not narrowed in the region between the intersection region and the first busbar 14. The widths of the plurality of second offset electrodes and the plurality of second electrode fingers 17 are also not narrowed in the region between the intersection region and the second busbar. As a result, the series resistance can be reduced.

In addition, in the present example embodiment, the same as or similar to the first example embodiment, the intersection region includes a plurality of curved regions, and the closer the excitation portion is to the first envelope or the second envelope, the smaller the duty ratio. As a result, the resonant frequencies or the anti-resonant frequencies can match or substantially match each other in all of the excitation portions, and the unnecessary wave outside the pass band and the transverse mode can be reduced or prevented.

Hereinafter, a first modified example and a second modified example of the third example embodiment will be described, in which only the configurations of the region between the intersection region and the first busbar 14 and the region between the intersection region and the second busbar are different from those of the third example embodiment. In the first modified example and the second modified example, the same as or similar to the third example embodiment, the resonant frequencies or the anti-resonant frequencies can match or substantially match each other in all of the excitation portions, the unnecessary wave outside the pass band and the transverse mode can be reduced or prevented, and the series resistance can be reduced.

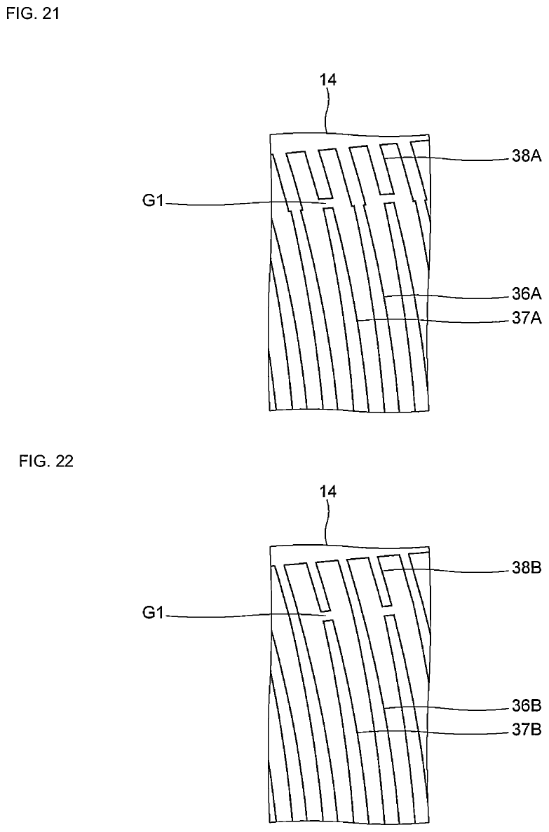

In the first modified example shown in FIG. 21, the width of the plurality of first offset electrodes 38A is wider than the width of the tip end portion of the plurality of second electrode fingers 37A. The width of the plurality of first electrode fingers 36A is the same or substantially the same as the width of the plurality of first offset electrodes 38A in the region in the outer side portion of the intersection region. Although not shown, the width of the plurality of second offset electrodes is wider than the width of the tip end portion of the plurality of first electrode fingers 36A. The width of the plurality of second electrode fingers 37A is the same or substantially the same as the width of the plurality of second offset electrodes in the region in the outer side portion of the intersection region.

Therefore, in the present modified example, the duty ratio in the region between the intersection region and the first busbar 14 is larger than the duty ratio in the portion in which the tip end portions of the plurality of second electrode fingers 37A are arranged. Similarly, the duty ratio in the region between the intersection region and the second busbar is larger than the duty ratio in the portion in which the tip end portions of the plurality of first electrode fingers 36A are arranged.

In the second modified example shown in FIG. 22, the shapes of the plurality of first offset electrodes 38B and the plurality of second offset electrodes in a plan view are linear.

Similarly, in the present modified example, the shapes of the plurality of first electrode fingers 36B and the plurality of second electrode fingers 37B in a plan view are linear in the region in the outer side portion of the intersection region.

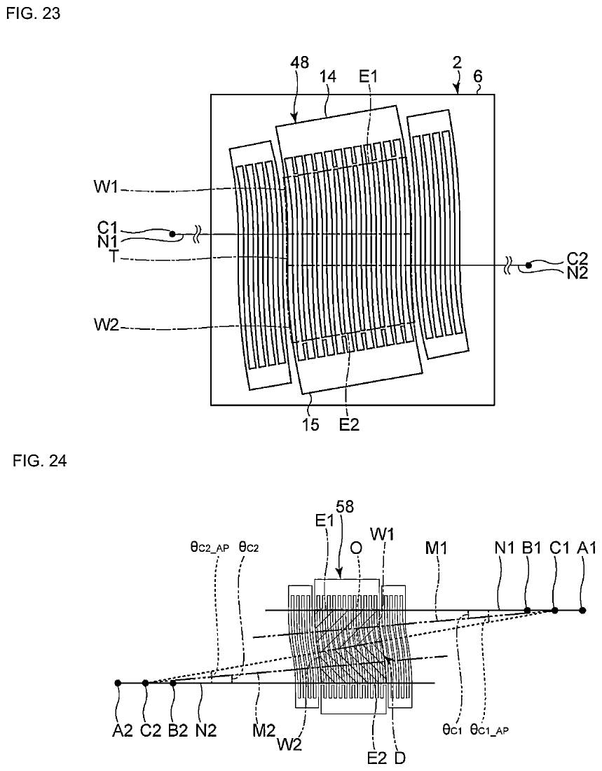

FIG. 23 is a schematic plan view of an acoustic wave device according to a fourth example embodiment of the present invention.

The present example embodiment is different from the first example embodiment in that the plurality of electrode fingers of the IDT electrode 48 include a linear portion. The present example embodiment is different from the first example embodiment in that two reference lines N1 and N2 are provided. More specifically, the reference line N1 is a reference line in the first curved region W1. The reference line N2 is a reference line in the second curved region W2. Except for the above points, the acoustic wave device according to the present example embodiment has the same or substantially the same configuration as the acoustic wave device 1 according to the first example embodiment.

The intersection region of the IDT electrode 48 includes the first curved region W1, the second curved region W2, and the straight line region T. The first curved region W1, the second curved region W2, and the straight line region T are arranged in a direction in which the first busbar 14 and the second busbar 15 face each other. More specifically, the first curved region W1 and the second curved region W2 face each other with the straight line region T interposed therebetween.

In the IDT electrode 48, each electrode finger includes two inflection points. Each inflection point is a point where an arc and a straight line are connected to each other. The extension line of the boundary line of the straight line region T and the first curved region W1 passes through the fixed point C1. The boundary line and the straight line including the extension line of the boundary line are the reference line N1 in the first curved region W1. The angle θn in the first curved region W1 is an angle between the straight line passing through the fixed point C1 and the excitation portion in the first curved region W1, and the reference line N1. In the present example embodiment, θ_{C1}=θ_{C1_prop}. On the other hand, the extension line of the boundary line of the straight line region T and the second curved region W2 passes through the fixed point C2. The boundary line and the straight line including the extension line of the boundary line are the reference line N2 in the second curved region W2. The angle θ_{C2} in the second curved region W2 is an angle between the straight line passing through the fixed point C2 and the excitation portion in the second curved region W2, and the reference line N2. In the present example embodiment, θ_{C2}=θ_{C2_prop}.

In the straight line region T, the excitation angle is constant. More specifically, at the boundary between the straight line region T and the first curved region W1, the excitation angle θ_{C1_prop} is about 0°. Similarly, at the boundary between the straight line region T and the second curved region W2, the excitation angle θ_{C2_prop} is about 0°. Therefore, the excitation angle of the excitation portion in the straight line region T corresponds to about 0°. The excitation angle of the excitation portion in the straight line region T need not necessarily be about 0°.

In the present example embodiment, in the entire or substantially the entire straight line region T, the direction of X propagation, which is the direction in which the propagation axis of the piezoelectric layer 6 extends, is orthogonal or substantially orthogonal to the direction in which the plurality of electrode fingers extend. Therefore, the straight line region T is a region that is stable with respect to the propagation axis. By providing the intersection region with the straight line region T, the change in the propagation direction can be reduced as a whole of the IDT electrode 48, and the propagation of the acoustic wave can be stabilized.

In the present example embodiment, the same as or similar to the first example embodiment, the intersection region includes a plurality of curved regions, and the closer the excitation portion is to the first envelope E1 or the second envelope E2, the smaller the duty ratio. As a result, the resonant frequencies or the anti-resonant frequencies can match or substantially match each other in all of the excitation portions, and the unnecessary wave outside the pass band and the transverse mode can be reduced or prevented.

Incidentally, the reference line in each curved region may be a straight line including the first envelope or the second envelope. The example will be described with reference to a fifth example embodiment of the present invention.

FIG. 24 is a schematic plan view for describing a configuration of an IDT electrode in the fifth example embodiment. In FIG. 24, each curved region is shown with hatching.

The present example embodiment is different from the first example embodiment in that two reference lines N1 and N2 are provided. The present example embodiment is different from the first example embodiment in that the closer the excitation portion is to the first envelope E1 or the second envelope E2, the larger the duty ratio. The present example embodiment is different from the first example embodiment in that the shapes of the plurality of electrode fingers in a plan view are the shapes in which two elliptical arcs are connected to each other.

Except for the above points, the acoustic wave device according to the present example embodiment has the same or substantially the same configuration as the acoustic wave device 1 according to the first example embodiment.

An extension line of the first envelope E1 passes through the fixed point C1. A straight line including the first envelope E1 and an extension line of the first envelope E1 is the reference line N1 in the first curved region W1. The angle between the straight line passing through the excitation portion in the first curved region W1, and the reference line N1 is the angle θm in the first curved region W1. In the first envelope E1, the angle θC is about 0°.

On the other hand, the extension line of the second envelope E2 passes through the fixed point C2. A straight line including the second envelope E2 and an extension line of the second envelope E2 is the reference line N2 in the second curved region W2. The angle between the straight line passing through the excitation portion in the second curved region W2, and the reference line N2 is the angle θ_{C2} in the second curved region W2. In the second envelope E2, the angle θ_{C2} is about 0°.

The straight line passing through the fixed point C1 and the fixed point C2 includes a boundary line O between the first curved region W1 and the second curved region W2. In the IDT electrode 58, the intersection angle θ_{C1_AP} in the first curved region W1 is an angle between a straight line passing through the first envelope E1 and the fixed point C1, and a straight line passing through the boundary line O and the fixed point C1. On the other hand, the intersection angle θ_{C2_AP} in the second curved region W2 is an angle between a straight line passing through the second envelope E2 and the fixed point C2, and a straight line passing through the boundary line O and the fixed point C2.

However, the straight line passing through the fixed point C1 and the fixed point C2 need not necessarily include the boundary line O between the first curved region W1 and the second curved region W2.

Even in the present example embodiment, the same as or similar to the first example embodiment, the duty ratio is changed according to the excitation angle θ_{C1_prop} such that the resonant frequencies or the anti-resonant frequencies of all of the excitation portions in the first curved region W1 match or substantially match each other. Similarly, the duty ratio is changed according to the excitation angle θ_{C2} prop such that the resonant frequencies or the anti-resonant frequencies of all of the excitation portions in the second curved region W2 match or substantially match each other. As a result, the resonant frequencies or the anti-resonant frequencies can match or substantially match each other in all of the excitation portions, and the unnecessary wave outside the pass band and the transverse mode can be reduced or prevented.

Incidentally, a configuration may be used in which a piston mode can be used. As a result, the energy in the main mode can be effectively confined to the center side of the intersection region, and the loss can be effectively reduced. Hereinafter, an example of a configuration in which the piston mode is generated is described as first to fourth modified examples of the fifth example embodiment.

In the case of the configuration using the piston mode, a portion on any straight line passing through the fixed point in a region of each of the curved regions, which is located in a central region described later, is defined as the excitation portion. In the first to fourth modified examples, the same as or similar to the fifth example embodiment, the closer the excitation portion is to the first envelope or the second envelope, the larger the duty ratio. As a result, the resonant frequencies or the anti-resonant frequencies can match or substantially match each other in all of the excitation portions, and the unnecessary wave outside the pass band and the transverse mode can be reduced or prevented.

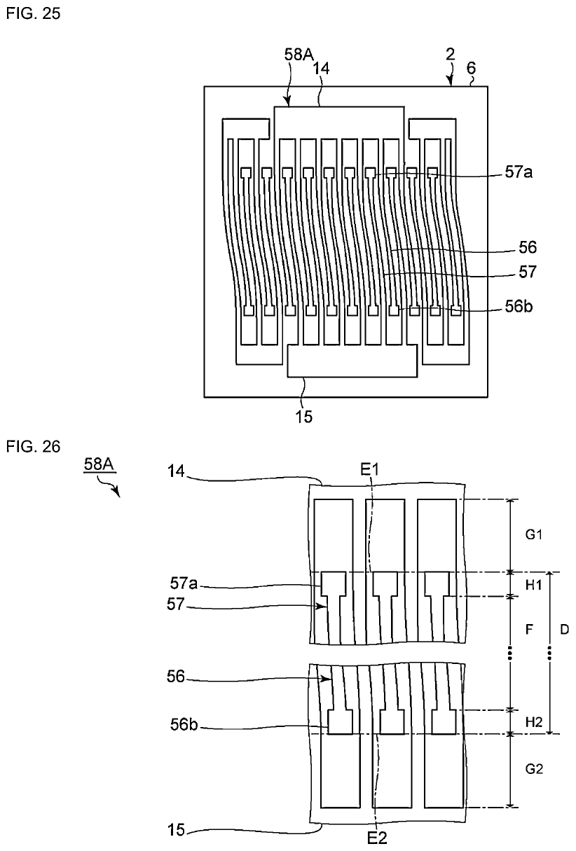

In the first modified example shown in FIG. 25, the first offset electrode and the second offset electrode are not provided. The same applies to other modified examples. In the present modified example, the plurality of first electrode fingers 56 include wide width portions 56b. The plurality of second electrode fingers 57 also include wide width portions 57a. More specifically, as shown in FIG. 26, the intersection region D of an IDT electrode 58A includes a central region F and a pair of edge regions. Specifically, the pair of edge regions is a first edge region H1 and a second edge region H2. The first edge region H1 includes the first envelope E1 as an end edge portion. The second edge region H2 includes the second envelope E2 as an end edge portion. The first edge region H1 and the second edge region H2 face each other with the central region F interposed therebetween.

In the first edge region H1, the wide width portion 57a is provided in the plurality of second electrode fingers 57. In the second edge region H2, the wide width portion 56b is provided in the plurality of first electrode fingers 56. The width of the electrode finger in the wide width portion is wider than the width of the electrode finger in the central region F. Since the wide width portion is provided in each of the electrode fingers, the acoustic velocity in both edge regions is lower than the acoustic velocity in the central region F. The shape of the electrode finger in the edge region may be a straight line or a curve. In addition, the shape of the wide width portion is not limited to a quadrangular shape, and may be a shape having the wide width portion at least in a portion thereof.

Furthermore, the IDT electrode 58A includes a pair of gap regions. Specifically, the pair of gap regions is a first gap region G1 and a second gap region G2. The first gap region G1 is located between the intersection region D and the first busbar 14. The second gap region G2 is located between the intersection region D and the second busbar 15.

As described above, the acoustic velocity in the first edge region H1 is lower than the acoustic velocity in the central region F. As a result, a low acoustic velocity region is formed in the first edge region H1. The low acoustic velocity region is a region where the acoustic velocity is lower than the acoustic velocity in the central region F. Similarly, a low acoustic velocity region is also provided in the second edge region H2.

On the other hand, in the first gap region G1, only the first electrode finger 56 is provided among the first electrode finger 56 and the second electrode finger 57. As a result, a high acoustic velocity region is provided in the first gap region G1. The high acoustic velocity region is a region where the acoustic velocity is higher than the acoustic velocity in the central region F. Similarly, a high acoustic velocity region is also provided in the second gap region G2.

In addition, the frequency of the acoustic wave propagating through the first edge region H1 may be lower than the frequency of the acoustic wave propagating through the central region F, and the frequency of the acoustic wave propagating through the first edge region H1 and the frequency of the acoustic wave propagating through the central region F may be lower than the frequency of the acoustic wave propagating through the first gap region G1. The frequency of the acoustic wave propagating through the first gap region G1 is a frequency when an acoustic wave having a wavelength defined in the first edge region H1 is excited and the acoustic wave propagates through the first gap region G1. The acoustic velocity of the central region F is defined in a case where a direction in which the tangent line of the electrode finger extends is in a range in which the direction in which the tangent line of the electrode finger extends in the first edge region H1 matches or substantially matches the direction in which the tangent line of the electrode finger extends. More specifically, the acoustic velocity in the central region F is defined when it is assumed that a direction in which the tangent line of the electrode finger extends is a direction in which an angle between the direction and a direction in which the tangent line of the electrode finger in the first edge region H1 extends is within a range of about +5° or less. In a case of discussing the frequency in the central region F, the frequency is not limited thereto.

In the present example embodiment, the central region F, a pair of low acoustic velocity regions, and a pair of high acoustic velocity regions are disposed in this order from the inner side portion to the outer side portion in the direction in which the first busbar 14 and the second busbar 15 face each other. As a result, a piston mode is generated.

A wide width portion may be provided in at least one of the plurality of electrode fingers in at least one of the first edge region H1 or the second edge region H2. However, it is preferable that the wide width portion is provided in the plurality of electrode fingers, and more preferable that the wide width portion is provided in all the electrode fingers.

As a result, the piston mode can be more reliably generated.

A low acoustic velocity region may be provided in at least one of the first edge region H1 or the second edge region H2. However, it is preferable that the low acoustic velocity region is provided in both the first edge region H1 and the second edge region H2. As a result, the piston mode can be more reliably generated.

In the present modified example, it is described that the IDT electrode 58A includes the pair of edge regions and the central region F. It is noted that the IDT electrodes of the fifth example embodiment and other example embodiments also include the pair of edge regions and the central region.

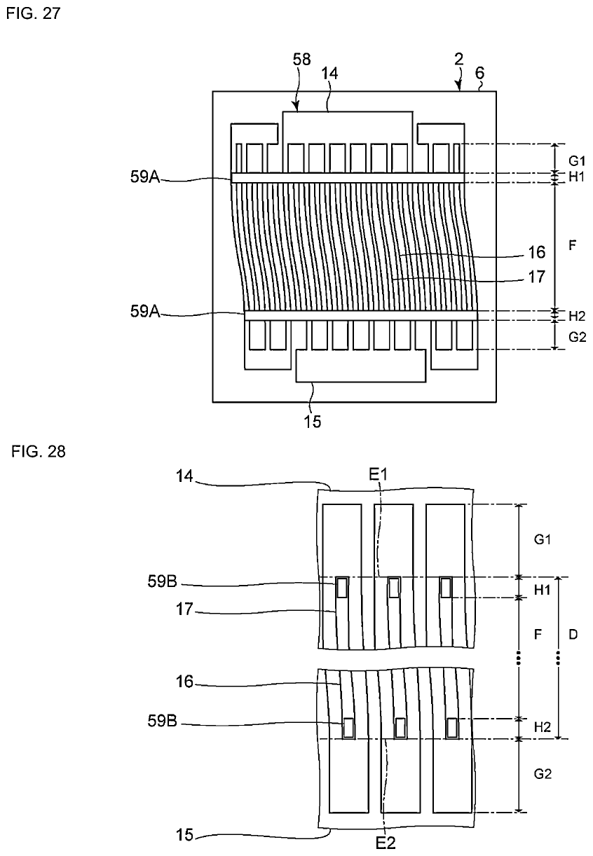

In the second modified example shown in FIG. 27, a mass-added film 59A is provided one by one in each of the first edge region H1 and the second edge region H2.

As a result, a low acoustic velocity region is provided in the first edge region H1 and the second edge region H2.

More specifically, each of the mass-added films 59A has a strip shape. One mass-added film 59A of a pair of mass-added films 59A is provided on a plurality of electrode fingers in the first edge region H1. Similarly, the other mass-added film 59A is provided on the plurality of electrode fingers in the second edge region H2. Each mass-added film 59A is also provided on the portion between the electrode fingers on the piezoelectric layer. As a material of the mass-added film 59A, an appropriate dielectric can be used.

The mass-added film 59A may be laminated with at least one electrode finger in the plurality of electrode fingers in at least one of the first edge region H1 and the second edge region H2. However, it is preferable that a plurality of electrode fingers are laminated with the mass-added film 59A, and more preferable that all of the electrode fingers are laminated with the mass-added film 59A. As a result, the piston mode can be more reliably generated.

In the present modified example, the first electrode fingers 16 and the second electrode fingers 17 are configured in the same or substantially the same manner as the fifth example embodiment. However, the first electrode finger 16 and the second electrode finger 17 may include a wide width portion the same as or similar to the first modified example.

In the third modified example shown in FIG. 28, a plurality of mass-added films 59B are provided in each of the first edge region H1 and the second edge region H2.

As a result, a low acoustic velocity region is provided in the first edge region H1 and the second edge region H2.

More specifically, in the present modified example, each of the mass-added films 59B is provided only on one electrode finger. In this case, as a material of the mass-added film 59B, an appropriate metal or dielectric can be used.

In the present modified example, the first electrode fingers 16 and the second electrode fingers 17 are configured in the same or substantially the same manner as the fifth example embodiment. However, the first electrode finger 16 and the second electrode finger 17 may include a wide width portion the same as or similar to the first modified example.

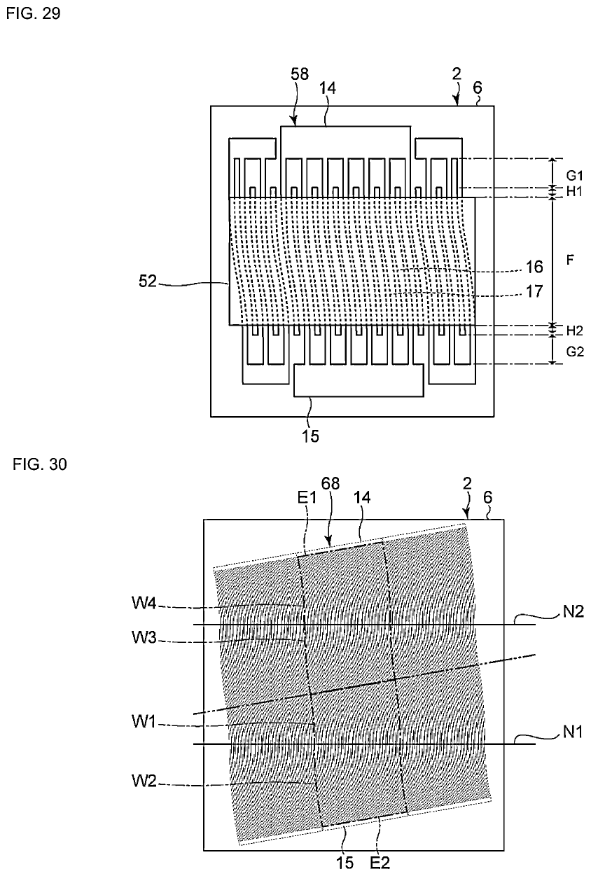

In the fourth modified example shown in FIG. 29, a high acoustic velocity film 52 is provided in the central region F of the IDT electrode 58, the same as or similar to the fifth example embodiment. As a result, the acoustic velocity in the central region F is high. Therefore, the acoustic velocities in the first edge region H1 and the second edge region H2 are lower than the acoustic velocity in the central region F. That is, the low acoustic velocity region is provided in both the first edge region H1 and the second edge region H2.

The high acoustic velocity film 52 may be provided in the central region F even in the configurations of the first to third modified examples. As a material of the high acoustic velocity film 52, for example, silicon nitride or the like can be used.

As described above, in the first to fourth modified examples, the duty ratio changes according to the excitation angle, the same as or similar to the fifth example embodiment. However, the present invention is not limited to the configuration in which the piston mode is used. As the excitation portion is closer to the first envelope or the second envelope, a value of at least one of the duty ratio, the electrode finger pitch, and the thicknesses of the plurality of first electrode fingers and the plurality of second electrode fingers may change in one of the direction in which the value increases and the direction in which the value decreases.

Alternatively, a parameter such as a thickness of the intermediate layer in the piezoelectric substrate, which affects the frequency, may be changed according to the excitation angle in each of the curved regions. In a case where a dielectric film is provided on the piezoelectric substrate to cover the IDT electrode, the thickness of the dielectric film may be changed according to the excitation angle in each of the curved regions. A plurality of the parameters among the above parameters may be changed according to the excitation angle in each of the curved regions. Even in these cases, the resonant frequencies or the anti-resonant frequencies can match or substantially match each other in all of the excitation portions.

FIG. 30 is a schematic plan view of an acoustic wave device according to a sixth example embodiment of the present invention.

The present example embodiment is different from the first example embodiment in that the IDT electrode 68 includes four curved regions. The present example embodiment is different from the first example embodiment in that the first curved region W1 does not include the first envelope E1. Except for the above points, the acoustic wave device according to the present example embodiment has the same or substantially the same configuration as the acoustic wave device 1 according to the first example embodiment.

The intersection region includes a third curved region W3 and a fourth curved region W4 in addition to the first curved region W1 and the second curved region W2. In a direction from the first envelope E1 toward the second envelope E2, the fourth curved region W4, the third curved region W3, the first curved region W1, and the second curved region W2 are arranged in this order. The fourth curved region W4 includes the first envelope E1. On the other hand, the second curved region W2 includes the second envelope E2.

When the first curved region W1 and the second curved region W2 are defined as a first set of curved regions and the third curved region W3 and the fourth curved region W4 are defined as a second set of curved regions, the first set of curved regions and the second set of curved regions have mutually inverted configurations. A two-dot chain line in FIG. 30 indicates a boundary line between the first curved region W1 and the third curved region W3 and an extension line thereof. In the present example embodiment, the boundary line is parallel to the first envelope E1 and the second envelope E2. However, the relationship of the configuration of each curved region is not limited to the above-described relationship. For example, in each curved region, parameters such as a duty ratio and an elliptical coefficient in the excitation portion in which the intersection angle and the excitation angle are about 0° may be different from each other.

The acoustic wave device according to the present example embodiment has two reference lines N1 and a reference line N2.

More specifically, the first set of curved regions is configured in the same or substantially the same manner as the intersection region of the first example embodiment. Therefore, in the first curved region W1 and the second curved region W2, the reference line N1 is common. Similarly, in the third curved region W3 and the fourth curved region W4, the reference line N2 is common.

In the present example embodiment, the duty ratio changes according to the excitation angle in each of the curved regions. As a result, the same as or similar to the first example embodiment, the resonant frequencies or the anti-resonant frequencies can match or substantially match each other in all of the excitation portions in all of the curved regions, and the unnecessary wave outside the pass band and the transverse mode can be reduced or prevented.

In addition, since the intersection region includes four curved regions, a standing wave is unlikely to be generated in a direction in which the first busbar 14 and the second busbar 15 face each other. Therefore, it is possible to effectively reduce or prevent the unnecessary wave outside the pass band and the transverse mode.

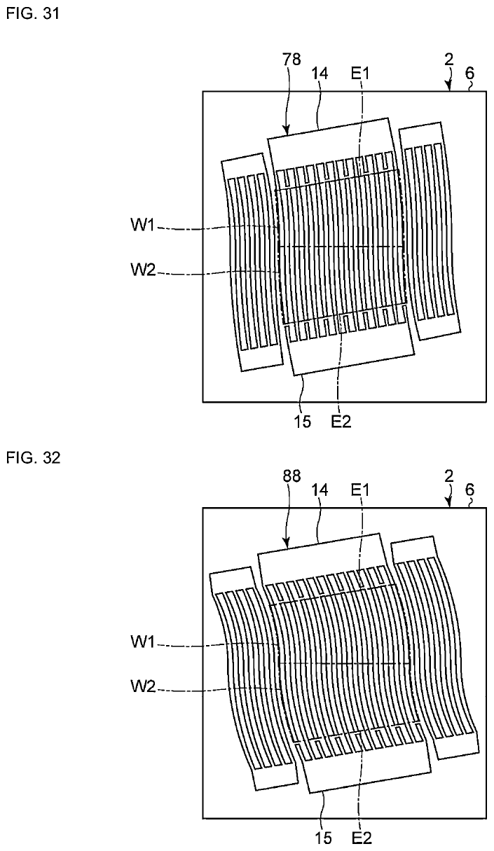

FIG. 31 is a schematic plan view of an acoustic wave device according to a seventh example embodiment of the present invention.

The present example embodiment is different from the first example embodiment in that the electrode finger pitch is not constant and an elliptical coefficient α2/α1 is larger than 1 in the IDT electrode 78. Except for the above points, the acoustic wave device according to the present example embodiment has the same or substantially the same configuration as the acoustic wave device 1 according to the first example embodiment. In the present example embodiment, both of the duty ratio and the electrode finger pitch are not constant.

More specifically, in the present example embodiment, in each of the first curved region W1 and the second curved region W2, the larger the absolute value of the excitation angle, the wider the electrode finger pitch. The larger the absolute value of the excitation angle, the smaller the duty ratio. As a result, the resonant frequencies or the anti-resonant frequencies can match or substantially match each other in all of the excitation portions. It is possible to disperse the unnecessary wave outside the pass band and the transverse mode, and to reduce or prevent the unnecessary wave outside the pass band and the transverse mode.

In the IDT electrode 78, both α12/α11 and α2²/α21 as the elliptical coefficient α2/α1 in the shapes of the plurality of electrode fingers are larger than 1. As a result, it is possible to reduce or prevent the response at an upper end of a stop band and to increase a value of a fractional stop band width. Details will be described below. The stop band is a region in which the wavelength of the acoustic wave is constant when the acoustic wave is confined to the metal grating having a periodic structure. The fractional stop band width is a value obtained by dividing the band width of the stop band by the resonant frequency fr. The upper end of the stop band is an end portion of the stop band on the higher band side. The band width of the stop band is a difference between the frequency at the upper end of the stop band and the resonant frequency fr.

In a case where the elliptical coefficient α2/α1 is larger than 1, the frequency at the upper end of the stop band is dispersed. As a result, it is possible to reduce or prevent the response of the frequency at the upper end of the stop band. In addition, a dimension of the intersection region in a direction in which the first busbar 14 and the second busbar 15 face each other is larger than a dimension of the intersection region in a direction orthogonal to the direction. Therefore, the curvature of the shapes of the plurality of electrode fingers in a plan view approaches 0. In this case, the band width of the stop band is widened. Therefore, the value of the fractional stop band width can be increased. At least one of the elliptical coefficients α12/α11 or α2²/α21 may be larger than 1.

Furthermore, in the present example embodiment, by using only the duty ratio, the value of the fractional band width can be made larger than in a case where the frequencies of each of the excitation portions match or substantially match each other. The fractional band width is represented by |fr-fa |/fr when the resonant frequency is defined as fr and the anti-resonant frequency is defined as fa.

An example of the design parameters of the acoustic wave device according to the present example embodiment will be described below.
Number of pairs of electrode fingers of IDT electrode: 60 pairs
Elliptical coefficient α12/α11 in the shape of the electrode finger: about 1.1.
Elliptical coefficient α2²/α21 in the shape of the electrode finger: about 1.1
Intersection Angle θ_{C1_AP}: about 10°
Intersection Angle θ_{C2_AP}: about 10°
Duty ratio: about 0.5 in the excitation portion in which the excitation angle θ_{C1_prop} and the excitation angle θ_{C2} prop are about 0°
Length of the first offset electrode and the second offset electrode: about 3.5 λ
Number of pairs of electrode fingers of reflector: 20 pairs

FIG. 32 is a schematic plan view of an acoustic wave device according to an eighth example embodiment of the present invention.

The present example embodiment is different from the first example embodiment in that the electrode finger pitch is not constant and an elliptical coefficient α2/α1 is smaller than 1 in the IDT electrode 88. Except for the above points, the acoustic wave device according to the present example embodiment has the same or substantially the same configuration as the acoustic wave device 1 according to the first example embodiment. In the present example embodiment, both of the duty ratio and the electrode finger pitch are not constant.

More specifically, in the present example embodiment, in each of the first curved region W1 and the second curved region W2, the larger the absolute value of the excitation angle, the narrower the electrode finger pitch. The larger the absolute value of the excitation angle, the smaller the duty ratio. As a result, the resonant frequencies or the anti-resonant frequencies can match or substantially match each other in all of the excitation portions. It is possible to disperse the unnecessary wave outside the pass band and the transverse mode, and to reduce or prevent the unnecessary wave outside the pass band and the transverse mode.

In the IDT electrode 88, both α12/α11 and α2²/α21 as the elliptical coefficients α2/α1 in the shapes of the plurality of electrode fingers in a plan view are smaller than 1. As a result, it is possible to reduce or prevent the response at the upper end of the stop band and to increase the value of the fractional stop band width. Details will be described below.

In a case where the elliptical coefficient α2/α1 is smaller than 1, the frequency at the upper end of the stop band is dispersed. As a result, it is possible to reduce or prevent the response of the frequency at the upper end of the stop band. In addition, the dimension of the intersection region in a direction in which the first busbar 14 and the second busbar 15 face each other is smaller than the dimension of the intersection region in a direction orthogonal to the direction. Therefore, the curvature is larger than that in a case where the shapes of the plurality of electrode fingers in a plan view are the circular or substantially circular arc shapes. In this case, an interval between the frequency at which the main mode occurs and the frequency at which the unnecessary wave occurs is widened. Therefore, the unnecessary waves can be effectively reduced or prevented. In addition to the above configuration, the frequencies of the excitation portions match or substantially match each other by both the duty ratio and the electrode finger pitch. As a result, by using only the duty ratio, unnecessary waves can be reduced or prevented as compared with a case where the frequencies of each of the excitation portions substantially match each other. At least one of the elliptical coefficients α12/α11 or α2²/α21 may be smaller than 1.

Furthermore, in the present example embodiment, by using only the duty ratio, the value of the fractional band width can be made smaller than in a case where the frequencies of each of the excitation portions substantially match each other.

An example of the design parameters of the acoustic wave device according to the present example embodiment will be described below.
Number of pairs of electrode fingers of IDT electrode: 60 pairs
elliptical coefficient α12/α11 in the shape of the electrode finger: about 0.9
elliptical coefficient α2²/α21 in the shape of the electrode finger: about 0.9
Intersection Angle θ_{C1}_AP: about 10°
Intersection Angle θ_{C2_AP}: about 10°
Duty ratio: about 0.5 in the excitation portion in which the excitation angle θ_{C1_prop} and the excitation angle θ_{C2_prop} are about 0°

Length of the first offset electrode and the second offset electrode: about 3.5λ Number of pairs of electrode fingers of reflector: 20 pairs

In the first to eighth example embodiments, by adjusting the duty ratio or the electrode finger pitch, the resonant frequencies or the anti-resonant frequencies match or substantially match each other in all of the excitation portions. However, the resonant frequencies or the anti-resonant frequencies of all of the excitation portions may match or substantially match each other by adjusting the thicknesses of the plurality of electrode fingers. This example will be described with reference to a ninth example embodiment of the present invention.

The ninth example embodiment is different from the first example embodiment in that the duty ratio is constant and the thickness of the plurality of electrode fingers is not constant in the IDT electrode. Except for the above points, the acoustic wave device according to the present example embodiment has the same or substantially the same configuration as the acoustic wave device 1 according to the first example embodiment.

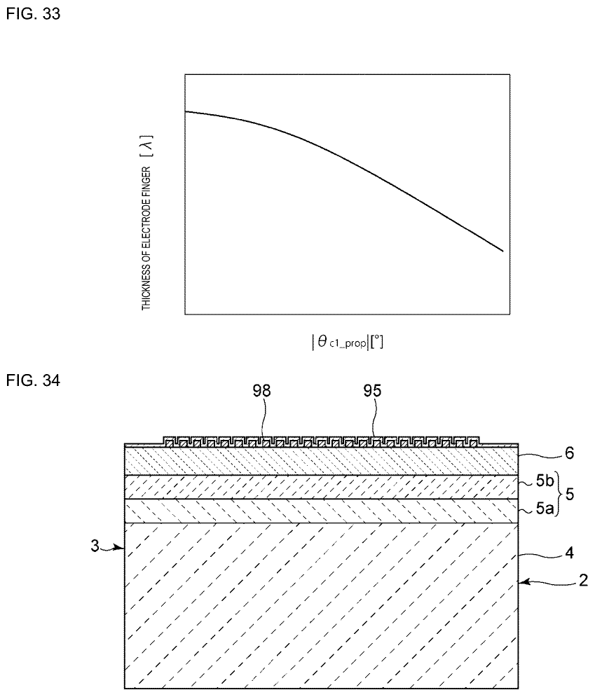

FIG. 33 is a graph showing a relationship between an absolute value of an excitation angle |θ_{C1_prop}| and a thickness of an electrode finger of the IDT electrode in the ninth example embodiment.

As shown in FIG. 33, in the first curved region of the IDT electrode, the larger the absolute value of the excitation angle |θ_{C1_prop}|, the thinner the thicknesses of the first electrode finger and the second electrode finger. In the ninth example embodiment, the relationship between the absolute value of the excitation angle |θ_{C2_prop|} in the second curved region and the thicknesses of the first electrode finger and the second electrode finger is also similar to the relationship shown in FIG. 33. As a result, the resonant frequencies or the anti-resonant frequencies match or substantially match each other in all of the excitation portions in the first curved region and the second curved region. Similar to the first example embodiment, it is possible to disperse the unnecessary wave outside the pass band and the transverse mode, and to reduce or prevent the unnecessary wave outside the pass band and the transverse mode.

The relationship between the thicknesses of the first electrode finger and the second electrode finger and the frequencies of each of the modes varies depending on the reverse-velocity surface of the piezoelectric substrate. Therefore, depending on the configuration of the piezoelectric substrate or the configuration on the piezoelectric substrate, when the larger the absolute values of the excitation angles |θ_{C1_prop}| and |θ_{C2_prop}|, the thicker the thickness of each electrode finger, the resonant frequencies or the anti-resonant frequencies may be matched or substantially matched each other in all of the excitation portions. Examples thereof include an acoustic wave device in which an IDT electrode provided on a substrate including only LiNbO₃ having a rotation Y-cut−4° X propagation is embedded in a SiO: film having a thick thickness. Alternatively, in the excitation portion in which the reference line N passes and the excitation angle θ_{C1_prop} and the excitation angle θ_{C1_prop} are about 0°, the values of the thicknesses of the first electrode finger and the second electrode finger are not necessarily maximum or minimum.

In the first to ninth example embodiments, the resonant frequencies or the anti-resonant frequencies of all of the excitation portions match or substantially match each other due to the configuration of the IDT electrode. However, the resonant frequencies or the anti-resonant frequencies of all of the excitation portions may match or substantially match each other by adjusting the thickness of the dielectric film covering the IDT electrode. This example will be described with reference to a tenth example embodiment and a modified example thereof.

FIG. 34 is a schematic elevational cross-sectional view of an acoustic wave device according to a tenth example embodiment of the present invention. FIG. 34 is a schematic cross-sectional view along the reference line N.

The present example embodiment is different from the first example embodiment in that the duty ratio is constant in the IDT electrode 98. The present example embodiment is also different from the first example embodiment in that the dielectric film 95 is provided on the piezoelectric layer 6 to cover the IDT electrode 98. Except for the above points, the acoustic wave device according to the present example embodiment has the same or substantially the same configuration as the acoustic wave device 1 according to the first example embodiment.

The acoustic of velocity the transversal wave propagating through the dielectric film 95 of the present example embodiment is lower than the acoustic velocity of the main mode propagating through the dielectric film 95. The thickness of the dielectric film 95 varies according to the excitation angle θ_{C1_prop} of the excitation portion in the first curved region covered with the dielectric film 95. Similarly, the thickness of the dielectric film 95 varies according to the excitation angle θ_{C2} prop of the excitation portion in the second curved region covered with the dielectric film 95.

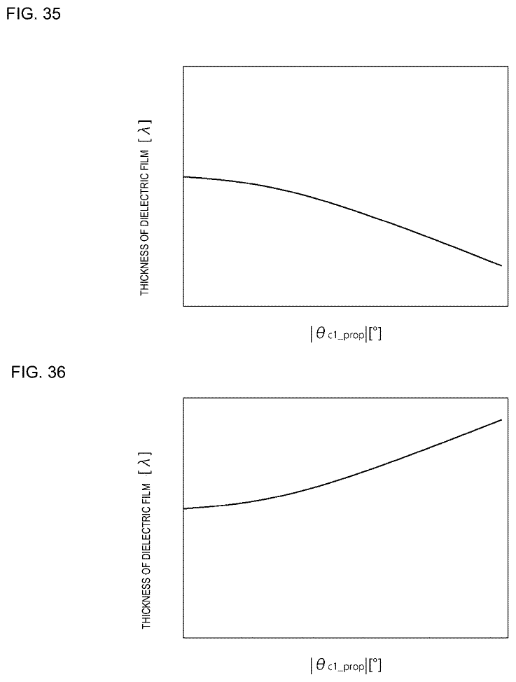

FIG. 35 is a graph showing a relationship between an absolute value of an excitation angle |θ_{C1_prop|} in an excitation portion of a first curved region covered with a dielectric film and a thickness of the dielectric film in the tenth example embodiment.

As shown in FIG. 35, in the present example embodiment, the larger the absolute value of the excitation angle |θ_{C1_prop}| of the excitation portion in the first curved region covered with the dielectric film 95, the thinner the thickness of the dielectric film 95. In the tenth example embodiment, a relationship between the absolute value of the excitation angle |θ_{C2_prop}| in the second curved region and the thickness of the dielectric film 95 is also the same as or similar to the relationship shown in FIG. 35. As a result, the resonant frequencies or the anti-resonant frequencies match or substantially match each other in all of the excitation portions in the first curved region and the second curved region. Similar to the first example embodiment, it is possible to disperse the unnecessary wave outside the pass band and the transverse mode, and to reduce or prevent the unnecessary wave outside the pass band and the transverse mode.

In the tenth example embodiment, the acoustic velocity of the transversal wave propagating through the dielectric film 95 is lower than the acoustic velocity of the main mode propagating through the dielectric film 95. However, the relationship of the acoustic velocity of the wave propagating through the dielectric film is not limited to the above-described relationship. A modified example of the tenth example embodiment in which only the acoustic velocity of the transversal wave propagating through the dielectric film is different from that of the tenth example embodiment will be described below.

In the modified example of the tenth example embodiment, the acoustic velocity of the transversal wave propagating through the dielectric film is higher than the acoustic velocity of the main mode propagating through the dielectric film. In the present modified example, a relationship between an absolute value of the excitation angle |θ_{C1_prop}| in the excitation portion in the first curved region covered with the dielectric film and the thickness of the dielectric film is shown in FIG. 36. More specifically, the larger the absolute value of the excitation angle |θ_{C1_prop}| in the excitation portion in the first curved region covered with the dielectric film, the thicker the thickness of the dielectric film. In the present modified example, the relationship between the absolute value of the excitation angle |θ_{C2_prop}| in the second curved region and the thickness of the dielectric film is also similar to the relationship shown in FIG. 36. As a result, the resonant frequencies or the anti-resonant frequencies match or substantially match each other in all of the excitation portions in the first curved region and the second curved region. Similar to the tenth example embodiment, it is possible to reduce or prevent the unnecessary wave outside the pass band and the transverse mode.

Depending on the configuration of the piezoelectric substrate, the value of the thickness of the portion in which the reference line N passes among the thicknesses of the portions covering the excitation portion in the dielectric film is not necessarily maximum or minimum.

Acoustic wave devices according to example embodiments of the present invention can be used, for example, in filter devices. This example will be described below.

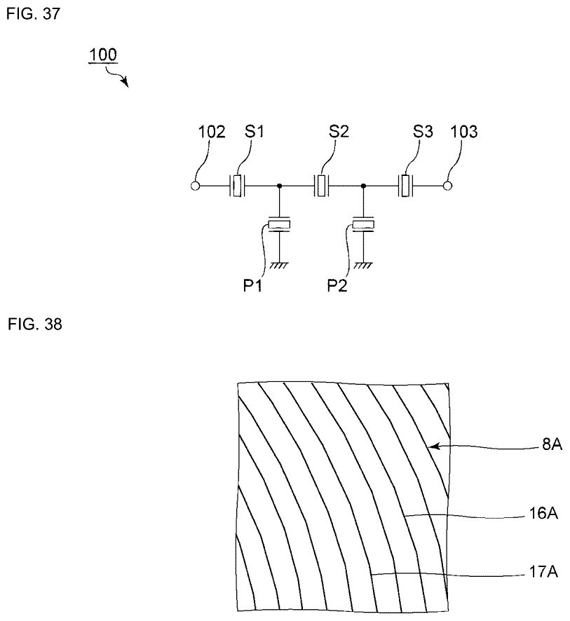

FIG. 37 is a circuit diagram of a filter device according to an eleventh example embodiment of the present invention.

The filter device 100 according to the present example embodiment is, for example, a ladder filter. The filter device 100 includes a first signal terminal 102, a second signal terminal 103, a plurality of series arm resonators, and a plurality of parallel arm resonators. In the filter device 100, all of the series arm resonators and all of the parallel arm resonators are acoustic wave resonators.

Furthermore, all of the series arm resonators and all of the parallel arm resonators are an acoustic wave devices according to an example embodiment of the present invention. However, at least one acoustic wave resonator of the plurality of acoustic wave resonators of the filter device 100 may be an acoustic wave device according to an example embodiment of the present invention.

The first signal terminal 102 is an antenna terminal. The antenna terminal is connected to an antenna. However, the first signal terminal 102 need not necessarily be an antenna terminal. The first signal terminal 102 and the second signal terminal 103 may be configured as, for example, electrode pads, or may be configured as wirings.

Specifically, the plurality of series arm resonators of the present example embodiment include a series arm resonator S1, a series arm resonator S2, and a series arm resonator S3. The plurality of series arm resonators are connected in series to each other between the first signal terminal 102 and the second signal terminal 103. Specifically, the plurality of parallel arm resonators include a parallel arm resonator P1 and a parallel arm resonator P2. The parallel arm resonator P1 is connected between a connection point between the series arm resonator S1 and the series arm resonator S2, and a ground potential. The parallel arm resonator P2 is connected between a connection point between the series arm resonator S2 and the series arm resonator S3, and the ground potential. The circuit configuration of the filter device 100 is not limited to the above-described configuration. The filter device 100 may include, for example, a longitudinally coupled resonator acoustic wave filter.

The acoustic wave resonator in the filter device 100 is an acoustic wave device according to an example embodiment of the present invention. Therefore, in the acoustic wave resonator of the filter device 100, it is possible to reduce or prevent the transverse mode and the unnecessary wave outside the pass band. As a result, it is also possible to reduce or prevent the unnecessary wave outside the pass band of the filter device 100.

Incidentally, the curve in the shapes of the plurality of electrode fingers in a plan view in the acoustic wave device according to each of the above-described example embodiments is a smooth curve. The curve in the shapes of the plurality of electrode fingers in a plan view may be a shape configured by connecting straight lines having a minute size. The curve in the shapes of the plurality of electrode fingers in a plan view may be a shape in which a plurality of vertices are connected to each other by the curve. Alternatively, the curve in the shapes of the plurality of electrode fingers in a plan view need not necessarily be a smooth curve. This example is described as a fifth modified example of the first example embodiment.

In the IDT electrode 8A in the fifth modified example shown in an enlarged manner in FIG. 38, the curve in the shape of each of the first electrode fingers 16A in a plan view is not a smooth curve. Specifically, the shape of each of the first electrode fingers 16A in a plan view is a shape configured by connecting the straight lines. The straight line in the shape is not a straight line having a minute size. More specifically, the length of the straight line in the shape is, for example, approximately several % of the total length of the first electrode finger 16A. However, in the shape, an angle between the connected straight lines is large, for example, about 160° or more and less than about 180°. Therefore, the shape of each of the first electrode fingers 16A in a plan view is a shape that can be approximated to a curve.

The shape of each of the second electrode fingers 17A in a plan view is also the same or substantially the same as the shape of each of the first electrode fingers 16A in a plan view. In the present modified example, similar to the first example embodiment, it is possible to reduce or prevent the unnecessary wave outside the pass band and the transverse mode.

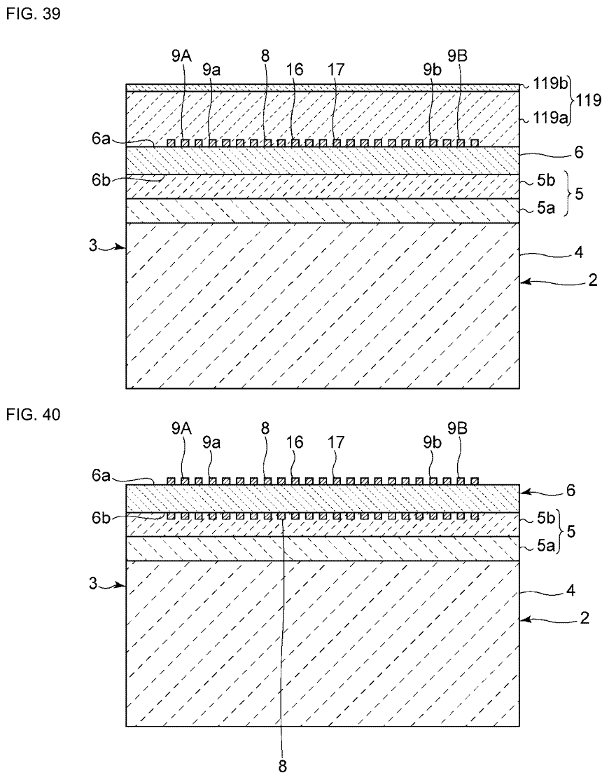

FIG. 39 is a schematic elevational cross-sectional view of an acoustic wave device according to a twelfth example embodiment of the present invention.

The present example embodiment is different from the first example embodiment in that the IDT electrode 8 is embedded in a protection film 119. Except for the above point, the acoustic wave device according to the present example embodiment has the same or substantially the same configuration as the acoustic wave device 1 according to the first example embodiment.

Specifically, the protection film 119 is provided on the piezoelectric layer 6 to cover the IDT electrode 8. The thickness of the protection film 119 is thicker than the thickness of the IDT electrode 8. The IDT electrode 8 is embedded in the protection film 119. As a result, the IDT electrode 8 is unlikely to be damaged.

The protection film 119 includes a first protection layer 119a and a second protection layer 119b. The IDT electrode 8 is embedded in the first protection layer 119a. The second protection layer 119b is provided on the first protection layer 119a. As a result, a plurality of advantageous effects can be achieved by the protection film 119. Specifically, in the present example embodiment, for example, silicon oxide is used as the material of the first protection layer 119a. As a result, the absolute value of a temperature coefficient of frequency (TCF) in the acoustic wave device can be reduced. Therefore, the temperature characteristics of the acoustic wave device can be improved. Silicon nitride, for example, is used for the second protection layer 119b. As a result, the humidity resistance of the acoustic wave device can be improved.

In addition, in the present example embodiment, the IDT electrode 8 is also configured in the same or substantially the same manner as the first example embodiment. As a result, it is possible to reduce or prevent an unnecessary wave outside the pass band and a transverse mode.

However, the materials of the first protection layer 119a and the second protection layer 119b are not limited to the above-described materials. The protection film 119 may include a single layer, or may include a multilayer body with three or more layers.

FIG. 40 is a schematic elevational cross-sectional view of an acoustic wave device according to a thirteenth example embodiment of the present invention.

The present example embodiment is different from the first example embodiment in that the IDT electrode 8 is provided on both main surfaces of the piezoelectric layer 6. Except for the above point, the acoustic wave device according to the present example embodiment has the same or substantially the same configuration as the acoustic wave device 1 according to the first example embodiment.

The piezoelectric layer 6 includes a first main surface 6a and a second main surface 6b. The first main surface 6a and the second main surface 6b face each other. The piezoelectric layer 6 in each of the above-described example embodiments similarly includes the first main surface 6a and the second main surface 6b. In each of the above-described example embodiments and the present example embodiment, the IDT electrode is provided on the first main surface 6a. In the present example embodiment, the IDT electrode 8 is also provided on the second main surface 6b. The IDT electrode 8 provided on the second main surface 6b is embedded in the second layer 5b of the intermediate layer 5.

The IDT electrode 8 provided on the first main surface 6a and the IDT electrode 8 provided on the second main surface 6b of the piezoelectric layer 6 face each other with the piezoelectric layer 6 interposed therebetween. In the acoustic wave device according to the present example embodiment, the IDT electrode 8 is configured in the same or substantially the same manner as the first example embodiment on the first main surface 6a. As a result, it is possible to reduce or prevent an unnecessary wave outside the pass band and a transverse mode.

For example, the IDT electrodes 8 provided on the first main surface 6a and the second main surface 6b of the piezoelectric layer 6 may have different design parameters.

Hereinafter, first to third modified examples of the thirteenth example embodiment, which are different from the thirteenth example embodiment in at least one of the configuration of the electrode provided on the second main surface of the piezoelectric layer and the multilayer structure of the piezoelectric substrate will be described. Even in the first to third modified examples, it is possible to reduce or prevent the unnecessary wave outside the pass band and the transverse mode, similar to the thirteenth example embodiment.

In the first modified example shown in FIG. 41, the layer configuration of the piezoelectric substrate 122 is different from that of the thirteenth example embodiment. Specifically, the piezoelectric substrate 122 includes a support substrate 4, a dielectric layer 125, and a piezoelectric layer 6. A dielectric layer 125 is provided on the support substrate 4. The piezoelectric layer 6 is provided on the dielectric layer 125. In the present modified example, the dielectric layer 125 has a frame shape. That is, the dielectric layer 125 includes a through-hole.

The support substrate 4 blocks one of the through-holes of the dielectric layer 125. The piezoelectric layer 6 blocks the other of the through-holes of the dielectric layer 125. As a result, a hollow portion 122c is provided in the piezoelectric substrate 122. A portion of the piezoelectric layer 6 and a portion of the support substrate 4 face each other with the hollow portion 122c interposed therebetween. The IDT electrode 8 provided on the second main surface 6b of the piezoelectric layer 6 is located inside the hollow portion 122c.

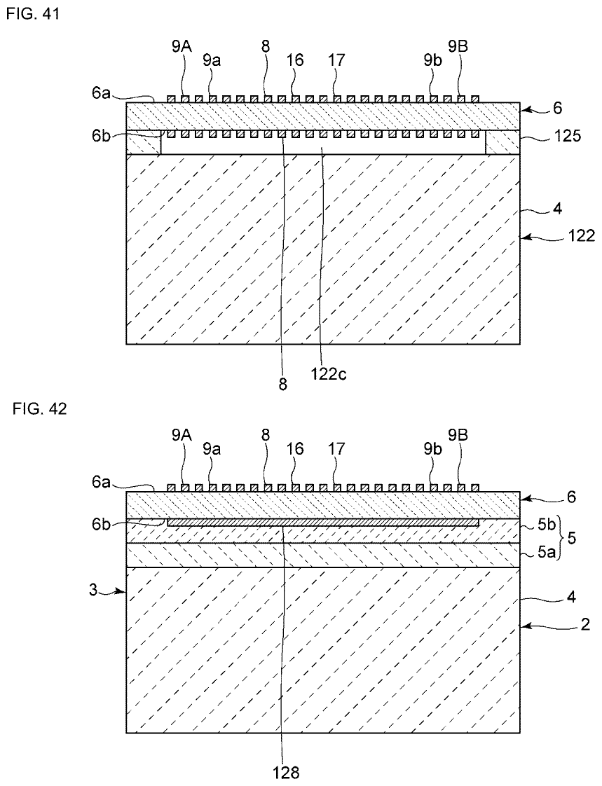

In the second modified example shown in FIG. 42, a plate-shaped electrode 128 is provided on the second main surface 6b of the piezoelectric layer 6. The IDT electrode 8 and the electrode 128 face each other with the piezoelectric layer 6 interposed therebetween.

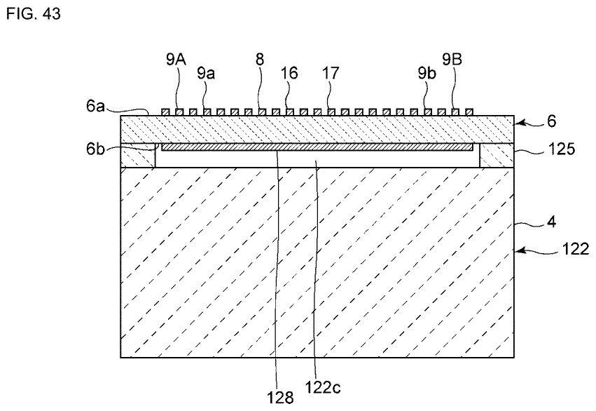

In the third modified example shown in FIG. 43, the piezoelectric substrate 122 is configured in the same or substantially the same manner as the first modified example, and the electrode 128 which is the same or substantially the same as that in the second modified example is provided on the second main surface 6b of the piezoelectric layer 6. The electrode 128 is located in the hollow portion 122c.

In the twelfth example embodiment, the thirteenth example embodiment, and each of the modified examples, an example of a case where the IDT electrode 8 has the same or substantially the same configuration as that in the first example embodiment is shown. However, each of the configurations of the twelfth example embodiment, the thirteenth example embodiment, and each modified example can also be provided in a case where the configuration of the IDT electrode is the configuration of the present invention other than the first example embodiment.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
an IDT electrode on the piezoelectric layer; wherein
the IDT electrode includes a first busbar and a second busbar facing each other, a plurality of first electrode fingers each including one end connected to the first busbar, and a plurality of second electrode fingers each including one end connected to the second busbar, the plurality of first electrode fingers and the plurality of second electrode fingers being interdigitated with each other;
a virtual line connecting tip ends of the plurality of second electrode fingers is defined as a first envelope, a virtual line connecting tip ends of the plurality of first electrode fingers is defined as a second envelope, and a region between the first envelope and the second envelope in the IDT electrode is an intersection region;
shapes of the plurality of first electrode fingers and the plurality of second electrode fingers in a plan view include at least two curved portions in which directions where a first electrode finger and a second electrode finger are bent are different from each other in the intersection region; and
in the intersection region, as a portion thereof is closer to the first envelope or the second envelope, a value of at least one of a duty ratio, an electrode finger pitch, or thicknesses of the plurality of first electrode fingers and the plurality of second electrode fingers changes in one of a direction in which the value increases and a direction in which the value decreases.

2. The acoustic wave device according to claim 1, wherein
each of the at least two curved portions in the shapes of the plurality of first electrode fingers and the plurality of second electrode fingers in a plan view includes a shape of a circular or substantially circular arc or an elliptical or substantially elliptical arc;
each of the shapes of the plurality of first electrode fingers and the plurality of second electrode fingers in a plan view includes at least one inflection point; and
the intersection region includes at least two curved regions in which each of the shapes of the plurality of first electrode fingers and the plurality of second electrode fingers in a plan view is a shape of a single circular or substantially circular arc or an elliptical or substantially elliptical arc.

3. The acoustic wave device according to claim 2, wherein
when a center of a circle including the circular or substantially circular arc in shapes of the first electrode finger and the second electrode finger or a midpoint of two focal points of an ellipse including the elliptical or substantially elliptical arc in each of the curved regions is defined as a fixed point, and a portion on any straight line passing through the fixed point in each of the curved regions is defined as an excitation portion, in the intersection region, since the excitation portion is closer to the first envelope or the second envelope, a value of at least one of a duty ratio, an electrode finger pitch, and thicknesses of the plurality of first electrode fingers and the plurality of second electrode fingers changes in one of a direction in which the value increases and a direction in which the value decreases.

4. An acoustic wave device comprising:
a piezoelectric substrate including a piezoelectric layer; and
an IDT electrode on the piezoelectric layer; wherein
the IDT electrode includes a first busbar and a second busbar facing each other, a plurality of first electrode fingers each including one end connected to the first busbar, and a plurality of second electrode fingers each including one end connected to the second busbar, the plurality of first electrode fingers and the plurality of second electrode fingers being interdigitated with each other;
a virtual line connecting tip ends of the plurality of second electrode fingers is defined as a first envelope, a virtual line connecting tip ends of the plurality of first electrode fingers is defined as a second envelope, and a region between the first envelope and the second envelope in the IDT electrode is an intersection region;
each of shapes of the plurality of first electrode fingers and the plurality of second electrode fingers in a plan view includes a shape of at least two circular or substantially circular arcs or elliptical or substantially elliptical arcs and includes at least one inflection point;
the intersection region includes at least two curved regions in which each of the shapes of the plurality of first electrode fingers and the plurality of second electrode fingers in a plan view is a shape of a single circular or substantially circular arc or an elliptical or substantially elliptical arc;
the intersection region includes a first edge region including the first envelope, a second edge region including the second envelope, and a central region interposed between the first edge region and the second edge region;
a low acoustic velocity region with an acoustic velocity lower than an acoustic velocity in the central region is provided in at least one of the first edge region and the second edge region; and
when a center of a circle including the circular or substantially circular arc in shapes of a first electrode finger and a second electrode finger or a midpoint of two focal points of an ellipse including the elliptical or substantially elliptical arc in each of the curved regions is defined as a fixed point, and a portion on any straight line passing through the fixed point in a region located in the central region of each of the curved regions is defined as an excitation portion, as the excitation portion is closer to the first envelope or the second envelope, a value of at least one of a duty ratio, an electrode finger pitch, or thicknesses of the plurality of first electrode fingers and the plurality of second electrode fingers changes in one of a direction in which the value increases and a direction in which the value decreases.

5. The acoustic wave device according to claim 4, wherein, in the first edge region, since the plurality of first electrode fingers and the plurality of second electrode fingers include wide width portions with widths wider than a width in the central region, the low acoustic velocity region is provided.

6. The acoustic wave device according to claim 4, further comprising:
a mass-added film provided in the first edge region; wherein
the low acoustic velocity region is defined by the mass-added film, the plurality of first electrode fingers, and the plurality of second electrode fingers being laminated on each other.

7. The acoustic wave device according to claim 4, further comprising:
a high acoustic velocity film in the central region; wherein
since the high acoustic velocity film is provided, the acoustic velocity in the central region is higher than acoustic velocities in the first edge region and the second edge region, and the low acoustic velocity region is provided in the first edge region and the second edge region.

8. The acoustic wave device according to claim 3, wherein
an extension line of a boundary line between the curved regions different from each other passes through the fixed point; and
in a case where a straight line including the boundary line and the extension line of the boundary line is defined as a reference line, an angle between a straight line passing through the fixed point and the excitation portion, and the reference line is defined, and an excitation angle of an angle between an excitation direction of an acoustic wave at an intersection of the straight line passing through the fixed point and the excitation portion, and the first electrode finger or the second electrode finger, and the reference line is defined, at least one of a duty ratio, an electrode finger pitch, or thicknesses of the plurality of first electrode fingers and the plurality of second electrode fingers changes according to the angle or the excitation angle, such that resonant frequencies or anti-resonant frequencies of all of the excitation portions match or substantially match each other.

9. The acoustic wave device according to claim 3, wherein
one curved region of a plurality of the curved regions includes the first envelope, and an extension line of the first envelope passes through the fixed point in the curved region; and
in a case where a straight line including the first envelope and the extension line of the first envelope is defined as a reference line, an angle between a straight line passing through the fixed point in the curved region including the first envelope and the excitation portion in the curved region, and the reference line is defined, and an excitation angle of an angle between an excitation direction of an acoustic wave at an intersection of the straight line passing through the fixed point and the excitation portion, and the first electrode finger or the second electrode finger, and the reference line is defined, at least one of a duty ratio, an electrode finger pitch, or thicknesses of the plurality of first electrode fingers and the plurality of second electrode fingers changes according to each of the angle and the excitation angle, such that resonant frequencies or anti-resonant frequencies of all of the excitation portions in the curved region match or substantially match each other.

10. The acoustic wave device according to claim 8, wherein
a piezoelectric single crystal is included as a material of the piezoelectric layer;
the piezoelectric layer includes a propagation axis; and
the propagation axis and the reference line extend parallel or substantially parallel to each other.

11. The acoustic wave device according to claim 8, wherein, as an absolute value of the angle or the excitation angle increases, the electrode finger pitch is reduced.

12. The acoustic wave device according to claim 8, wherein, as absolute values of the angle and the excitation angle increase, the electrode finger pitch increases.

13. The acoustic wave device according to claim 8, wherein, as absolute values of the angle and the excitation angle increase, thicknesses of the first electrode finger and the second electrode finger decrease.

14. The acoustic wave device according to claim 8, wherein, as absolute values of the angle and the excitation angle increase, thicknesses of the first electrode finger and the second electrode finger increase.

15. The acoustic wave device according to claim 8, further comprising:
a dielectric film on the piezoelectric layer and covering the IDT electrode; wherein
as absolute values of the angle and the excitation angle increase, a thickness of the dielectric film decreases.

16. The acoustic wave device according to claim 8, further comprising:
a dielectric film on the piezoelectric layer and covering the IDT electrode; wherein
as absolute values of the angle and the excitation angle increase, a thickness of the dielectric film increases.

17. The acoustic wave device according to claim 8, wherein, as absolute values of the angle and the excitation angle increase, a duty ratio decreases.

18. The acoustic wave device according to claim 8, wherein, as an absolute value of the angle or the excitation angle increases, a duty ratio increases.

19. The acoustic wave device according to claim 17, further comprising:
a plurality of first offset electrodes; and
a plurality of second offset electrodes; wherein
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed therebetween, and a tip end portion of the first electrode finger and a tip end portion of a second offset electrode face each other with a gap interposed therebetween;
a shape of the plurality of first offset electrodes includes a shape of a circular or substantially circular arc included in a circle centered on the fixed point or an elliptical or substantially elliptical arc included in an ellipse with the fixed point as a midpoint of two focal points; and
in a region between the first busbar and the intersection region, the closer to the first busbar, the smaller a duty ratio.

20. The acoustic wave device according to claim 18, further comprising:
a plurality of first offset electrodes; and
a plurality of second offset electrodes; wherein
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed therebetween, and a tip end portion of the first electrode finger and a tip end portion of a second offset electrode face each other with a gap interposed therebetween;
a shape of the plurality of first offset electrodes includes a shape of a circular or substantially circular arc included in a circle centered on the fixed point or an elliptical or substantially elliptical arc included in an ellipse with the fixed point as a midpoint of two focal points; and
in a region between the first busbar and the intersection region, the closer to the first busbar, the larger a duty ratio.

21. The acoustic wave device according to claim 3, further comprising:
a plurality of first offset electrodes; and
a plurality of second offset electrodes; wherein
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed therebetween, a tip end portion of the first electrode finger and a tip end portion of a second offset electrode face each other with a gap interposed therebetween;
a shape of the plurality of first offset electrodes includes a shape of a circular or substantially circular arc included in a circle centered on the fixed point or an elliptical or substantially elliptical arc included in an ellipse with the fixed point as a midpoint of two focal points; and
in a region between the first busbar and the intersection region, a duty ratio is constant.

22. The acoustic wave device according to claim 3, further comprising:
a plurality of first offset electrodes; and
a plurality of second offset electrodes; wherein
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed therebetween, a tip end portion of the first electrode finger and a tip end portion of a second offset electrode face each other with a gap interposed therebetween; and
the first offset electrode has a linear shape.

23. The acoustic wave device according to claim 3, wherein, when α2/α1 is defined as an elliptical coefficient of the shapes of the plurality of first electrode fingers and the plurality of second electrode fingers in a plan view, the shapes of the first electrode finger and the second electrode finger in a plan view include a portion in which α2/α1>about 1.

24. The acoustic wave device according to claim 3, wherein, when α2/α1 is defined as an elliptical coefficient of the shapes of the plurality of first electrode fingers and the plurality of second electrode fingers in a plan view, the shapes of the first electrode finger and the second electrode finger in a plan view include a portion in which α2/α1<about 1.

25. The acoustic wave device according to claim 3, wherein, when α2/α1 is defined as an elliptical coefficient of the shapes of the plurality of first electrode fingers and the plurality of second electrode fingers in a plan view, the shapes of the first electrode finger and the second electrode finger in a plan view include a portion in which α2/α1=about 1.

26. The acoustic wave device according to claim 1, wherein the shapes of the first electrode finger and the second electrode finger in a plan view include a linear shape.

27. The acoustic wave device according to claim 1, wherein
the piezoelectric substrate includes a support substrate; and
the piezoelectric layer is on the support substrate.

28. The acoustic wave device according to claim 27, wherein the piezoelectric substrate includes an intermediate layer between the support substrate and the piezoelectric layer.

29. The acoustic wave device according to claim 1, wherein the piezoelectric substrate includes only the piezoelectric layer.

30. A filter device comprising:
a plurality of acoustic wave resonators; wherein
at least one of the plurality of acoustic wave resonators is the acoustic wave device according to claim 1.

31. A filter device comprising:
a plurality of acoustic wave resonators; wherein
at least one of the acoustic wave resonators is the acoustic wave device according to claim 4.
